(19) United States
(12) Patent Application Publication
(10) Pub. No.: US 2023/0185536 A1
(43) Pub. Date: Jun. 15, 2023

(54) SIGNAL RANDOMNESS VALUE ESTIMATION

(71) Applicant: ARIEL SCIENTIFIC INNOVATIONS LTD., Ariel (IL)

(72) Inventors: Monika PINCHAS, Beit Dagan (IL); Yehonatan AVRAHAM, Beit El (IL)

(73) Assignee: ARIEL SCIENTIFIC INNOVATIONS LTD., Ariel (IL)

(21) Appl. No.: 17/924,067

(22) PCT Filed: May 13, 2021
(86) PCT No.: PCT/IL2021/050554

§ 371 Date: Nov. 8, 2022

Related U.S. Application Data
(60) Provisional application No. 63/045,115, filed on Jun. 28, 2020.
(60) Provisional application No. 63/024,621, filed on May 14, 2020.

(51) Int. Cl. G06F 7/58

(52) U.S. Cl. CPC G06F 7/582

(57) ABSTRACT

A system comprising at least one hardware processor and a non-transitory computer-readable storage medium having stored thereon program code, the program code executable by the at least one hardware processor to receive a sequence comprising n bits, apply a transformation to the sequence to obtain a time-frequency signal representation of the sequence, analyze the signal to measure one or more intensity values of the transformed sequence, and determine the presence of a periodic segment within the sequence when one of the intensity values deviates from a specified value range.

### CROSS-REFERENCE TO RELATED APPLICATIONS

This application claims the benefit of U.S. Provisional Application Ser. No. 63/024,621, filed May 14, 2020, and of U.S. Provisional Application Ser. No. 63/045,115, filed Jun. 28, 2020, the content of which is incorporated by reference herein by reference in its entirety.

### FIELD OF THE INVENTION

The invention relates generally to the field of pseudorandom number generator tests.

### BACKGROUND

A random number generator (RNG) generates a sequence of signs (numbers) ideally without any visible deterministic pattern or order. There are two principal methods used to generate random numbers. The first method measures some physical phenomenon that is expected to be random and then compensates for possible biases in the measurement process. Various natural phenomena, such as thermal noise, appear to be random and can be used as a basis for hardware, i.e., true random number generators (TRNGs). The advantage of true random number generators is in that the output is considered a “real” random number, however, most TRNGs suffer from some bias that affects their randomness. For example, TRNGs are sensitive to external influences such as temperature, power supply, obsolescence or other effects, and may suffer from a slow and persistent deterioration that is not noticeable. Sometimes errors such as hardware level errors are difficult to detect. Even with the best random source possible, it is not easy to ensure that the random numbers generated by the generator are not completely unbiased.

The second method uses computational algorithms that can produce long sequences of apparently random results, which are in fact completely determined by a shorter initial value, known as a seed value or key. The quality of RNG systems that are based on software, i.e., pseudorandom number generators (PRNG), isn't optimal since it is deterministic. Most of the PRNGs successfully pass statistical tests to make sure they have no pattern.

Random number generators typically undergo one or more statistical tests in order to verify the output quality of the random number generator. International standards organizations publish various standards for testing random and random pseudo-generators. There are mathematical methods for estimating random output entropy, which are effective in identifying characteristics of lack of randomness.

The foregoing examples of the related art and limitations related therewith are intended to be illustrative and not exclusive. Other limitations of the related art will become apparent to those of skill in the art upon a reading of the specification and a study of the figures.

### SUMMARY

The following embodiments and aspects thereof are described and illustrated in conjunction with systems, tools and methods which are meant to be exemplary and illustrative, not limiting in scope.

There is provided, in an embodiment, a system comprising at least one hardware processor and a non-transitory computer-readable storage medium having stored thereon program code, the program code executable by the at least one hardware processor to receive a sequence comprising n bits, apply a transformation to the sequence to obtain a time-frequency signal representation of the sequence, analyze the signal to measure one or more intensity values of the transformed sequence, and determine the presence of a periodic segment within the sequence when one of the intensity values deviates from a specified value range.

There is also provided, in an embodiment, a method comprising receiving a sequence comprising n bits; applying a transformation to the sequence to obtain a time-frequency signal representation of the sequence; analyzing the signal to measure one or more intensity values of the transformed sequence; and determining the presence of a periodic segment within the sequence when one of the intensity values deviates from a specified value range.

There is further provided, in an embodiment, a computer program product comprising a non-transitory computer-readable storage medium having program code embodied therewith, the program code executable by at least one hardware processor to: receive a sequence comprising n bits; apply a transformation to the sequence to obtain a time-frequency signal representation of the sequence; analyze the signal to measure one or more intensity values of the transformed sequence; and determine the presence of a periodic segment within the sequence when one of the intensity values deviates from a specified value range.

In some embodiments, the sequence is generated by a random number generator.

In some embodiments, the transformation comprises applying a Wigner distribution function to the sequence to obtain the time-frequency signal representation.

In some embodiments, the program instructions are further executable to transform, and the method comprises transforming, the sequence into an analytic signal. In some embodiments, the transformation comprises applying a Hilbert transform to the sequence.

In some embodiments, the program instructions are further executable to apply, and the method comprises applying, a time domain analysis to the time-frequency signal, to obtain a vector representing a distribution of a shape parameter associated with the time-frequency signal.

In some embodiments, the analyzing comprises analyzing the distribution of the shape parameter to detect the deviations.

In some embodiments, the deviations are detected based on at least one of: a maximum intensity peak, a width of an intensity peak, position of an intensity peaks, a number of intensity peaks, and a ratio between two or more intensity peaks,

In some embodiments, the program instructions are further executable to correct, and the method further comprises correcting, at least one of the detected periodic segments.

In addition to the exemplary aspects and embodiments described above, further aspects and embodiments will become apparent by reference to the figures and by study of the following detailed description.

### BRIEF DESCRIPTION OF THE FIGURES

Exemplary embodiments are illustrated in referenced figures. Dimensions of components and features shown in the figures are generally chosen for convenience and clarity of presentation and are not necessarily shown to scale. The figures are listed below.

FIG. 1, which is a flowchart of functional steps in a method for estimating a value of signal randomness outputted by an RNG, in accordance with some embodiments of the present invention;

FIGS. 2A and 2B are schematic illustrations of the standard normal distribution and the chi square distribution;

FIGS. 3A and 3B show a graph that does not depict any cyclicality and a graph that depicts cyclicality, indicating poor randomness;

FIG. 4 shows an algorithm block diagram, in accordance with some embodiments of the present disclosure;

FIG. 5 shows the periodic signal for f=10 [MHz];

FIG. 6, which shows the periodic signal for f₁=3 [MHz], f₂=7 [MHz], and f₃=10 [MHz];

FIGS. 7A and 7B show two random sequences;

FIGS. 8A, 8B, and 8C show exemplary random sequences with a periodic section;

FIG. 9 is a schematic diagram depicting a method and system 9000 for checking and providing correcting instruction of a signal supposed to be random, according to embodiments of the present invention;

FIG. 10A shows an exemplary resulting vector image after GGD activation (time plane);

FIG. 10B shows an exemplary shape parameter signal after execution;

FIG. 11A shows an exemplary histogram operation on the signal of the shape parameter;

FIG. 11B is an exemplary histogram according to test 6;

FIG. 11C is an exemplary histogram according to test 7. The histogram on the left is for a random sequence and on the right is for a non-random sequence;

FIG. 12 shows three different kinds of averages carried out on the tested averaged vector G[n], in accordance with some embodiments of the present disclosure;

FIGS. 13A-13C depict simulated results obtained for a non-random sequence where the averaged vector G[n] was compared to three different kind of averages, in accordance with some embodiments of the present disclosure;

FIG. 14A-14C show exemplary results of the algorithm (rectangular notation) that is pasted on the signal obtained after GGD, in accordance with some embodiments of the present disclosure; and

FIG. 15 is a block diagram of a computing system according to embodiments of the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION

The following embodiments and aspects thereof are described and illustrated in conjunction with systems, tools and methods which are meant to be exemplary and illustrative, not limiting in scope.

Disclosed herein are a method, system, and computer program product for estimating a randomness of a sequence. In some embodiments, the sequence is generated by a random number generator (RNG). In some embodiments, the present disclosure further provides for correcting detected periodicity in one or more segments of a sequence, to improve overall randomness of the sequence.

A sequence of n bits may be described as random if, at any point in the generation of the sequence, the occurrence of a zero or one is equally likely, i.e., the probability of each is exactly ½. The expected number of zeros (or ones) is n/2, where n=the sequence length.

The randomness of a given sequence is typically evaluated using various statistical tests that compare and evaluate the sequence against a truly random sequence. Randomness is a probabilistic property, wherein the properties of a random sequence can be characterized and described in terms of probability. Thus, the likely outcome of statistical tests, when applied to a truly random sequence, is known a priori and can be described in probabilistic terms.

In some embodiments, the present disclosure provides for an algorithm for estimating a degree of randomness of a sequence. In some embodiments, the present algorithm provides for detecting periodic features in the sequence, wherein periodicity is associated with repetitive patterns that are near each other within the sequence, and thus decreases randomness. In some embodiments, the present algorithm identifies one or more periodic segments within the sequence. In some embodiments, the present algorithm provides for locating positions of one or more periodic segments within the sequence. In some embodiments, the present algorithm further provides for correcting one or more periodic segments within the sequence, such that the overall degree of randomness of the sequence increases.

In some embodiments, the present algorithm provides for evaluating a sequence of bits. In some embodiments, the sequence is inputted into an algorithm of the present disclosure. In some embodiments, the sequence is generated by a PRNG or a TRNG. In some embodiments, a test sequence comprises a series of n bits, e.g., wherein n=between 10³ and 10⁷ bits.

In some embodiments, an algorithm of the present disclosure receives a sequence comprising n bits, wherein the sequence is obtained from a random number generator. In some embodiments, the sequence represents a non-stationary signal, e.g., the information encoded in the signal is not linear but rather quadratic in the time domain.

Accordingly, in some embodiments, a time-frequency transformation may be applied to the sequence, e.g., based on a Wigner distribution analysis and/or similar and/or additional analyses. In some embodiments, the time-frequency analysis provides a quadratic matrix which represents the sequence behavior in the time and frequency planes.

In some embodiments, a further transformation is performed of the signal into a discrete time, using, e.g., a Hilbert transformation. In some embodiments, this action is performed in order to avoid any aliasing phenomenon of the signal itself. This transformation provides for transforming the signal into an analytic signal, i.e., one which has no negative frequency components.

In some embodiments, the transformed signal may further be analyzed to evaluate distribution in the time domain using, e.g., a general gaussian distribution (GGD) analysis. In some embodiments, applying a time domain analysis converts the quadratic matrix into a vector, where the values are a new parameter that characterizes the signal behavior in the time plane. In some embodiments, applying a time domain analysis provides for obtaining a vector representing a shape parameter of the distribution. In some embodiments, the shape parameter allows characterizing the matrix obtained after the time-frequency analysis, so that each row or column in the matrix can be expressed by a single value. In some embodiments, a vector may be obtained which characterizes the time or frequency planes through the shape parameter, where in places where there is periodicity in the underlying sequence, the value of the shape parameter can be expected to change.

In some embodiments, a detection stage is then applied to the obtained shape parameters analysis. In some embodiments, the detection stage may be configured to extract one or more indices from the signal. In some embodiments, the one or more indices relate to distribution of intensity value in the signal. In some embodiments, the one or more indices are associated with one or more of a position, a dimension, a number of occurrences of peaks in the signal, of bins in the signal, and/or of abnormalities in the signal.

In some embodiments, the one or more indices comprise one or more of a location of a peak, a dimension of a peak, a number of peaks within a signal, a ratio between two or more peaks, a height of the frequency bin, a height of the frequency bin in relation to time, a maximum value of a frequency bin, a position of the frequency bin, a position of the maximum value of the frequency bin, a position of the maximum value of the frequency bin in relation to the time plan and/or the frequency plane, a ratio between two or more frequency bins, and abnormalities in the shape of the signal one or more planes.

In some embodiments, the present algorithm is configured to determine a presence of a periodicity within a sequence of bits, based, at least in part, on a deviation of the one or more indices from a threshold value. For example, in some embodiments, a periodicity is present if the difference between two or more peaks is larger than 15%. For example, in some embodiments, a periodicity is present if the maximum bin height in time is lower than 1.28 or greater than 1.4.

In some embodiments, the present algorithm is configured to output data representing the signal. In some embodiments, the output data comprises one or more of a graph and a numerical representation of the signal. In some embodiments, the algorithm is configured to output data representing the periodicity in relation to said signal and/or said sequence. For example, in some embodiments, the periodicity is marked on the graph of output data.

In some embodiments, the present algorithm further comprises a correction function configured to correct the received sequence under test, based, at least in part, on the identified periodic segments in the sequence. In some embodiments, the correction function increases the degree of randomness of the sequence. In some embodiments, the correction function corrects for periodicities by increasing a randomness parameter of the identified periodic segments. In some embodiments, the correction function removes the periodic segments from the sequence, thereby improving overall randomness of the sequence.

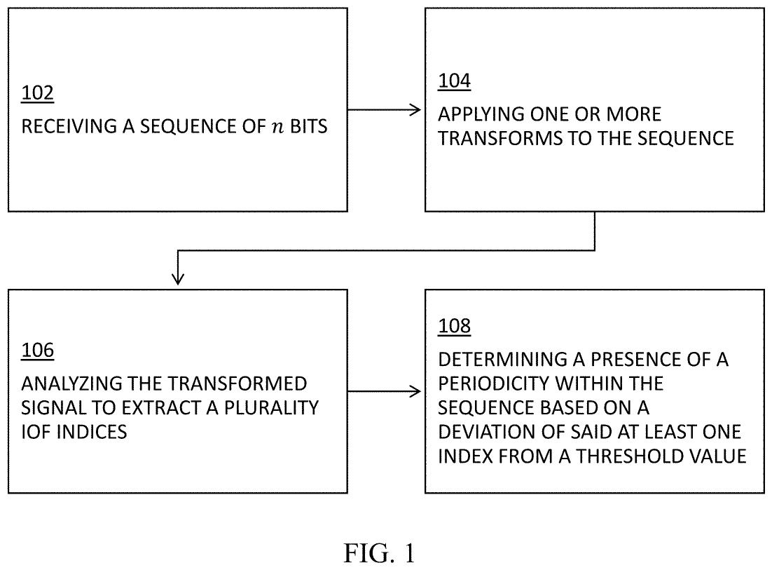

Reference is made to FIG. 1, which is a flowchart of the functional steps in a method for estimating a degree of sequence randomness, in accordance with some embodiments of the present invention.

In some embodiments, at step 102, the method comprises receiving a sequence of n bits for evaluation.

In some embodiments, at step 104, the method comprises applying one or more transformations to the received sequence under evaluation. In some embodiments, the method comprises first applying a signal processing analysis to derive an analytic representation of the sequence under evaluation, e.g., a Hilbert transform. In some embodiments, additional and/or other transforms may be applied. In some embodiments, a Hilbert transform converts the sequence under evaluation into a time-dependent signal. In some embodiments, the method comprises transforming the signal from continuous time to discrete time. In some embodiments, the method comprises transforming the signal from continuous time to discrete time using the Hilbert transformation.

In some embodiments, the method further comprises applying a time-frequency transform, e.g., a Wigner transform, to obtain a quadratic matrix which represents the sequence behavior in the time and frequency domains. In some embodiments, Wigner transform provides a Fourier transform of an autocorrelation parameter in the sequence under evaluation.

In some embodiments, the method further comprises simplifying the signal using a distribution analysis, e.g., a GGD. In some embodiments, the method comprises performing a GGD on the signal resulted from one or more of the Wigner distribution, the Hilbert transformation, and/or other transformations. In some embodiments, the GGD provides for detecting changes in the time plane. In some embodiments, applying a GGD comprises an operation that reverses the Wigner matrix into a vector, where the values of the vector are a shape parameter that characterizes the signal behavior in the time plane. In some embodiments, using a GDD function on the received result from the Wigner function simplifies the result, and therefore increases the ability to determine whether the signal is random and to trace the periodic segment in the sequence under evaluation. Additionally, the use of GGD allows for application in more complex cases such as very low periodicity.

In some embodiments, at step 106, the method comprises analyzing the transformed signal. In some embodiments, the method comprises identifying one or more indices within the signal. In some embodiments, the method comprises applying one or more tests to the signal. In some embodiments, the one or more tests include comparing the signal to a normal distribution. In some embodiments, the one or more tests include comparing between a plurality of peaks or a plurality of frequency bins of the signal. In some embodiments, the one or more tests include comparing between one or more axes of the signal and one or more of the peaks and the frequency bins of the signal.

In some embodiments, the method comprises extracting the one or more indices. In some embodiments, the one or more indices include at least one of a position, a dimension, a number of occurrences, and a relative ratio of at least one peak of the signal, or at least one frequency bin of the signal. In some embodiments, the method comprises comparing the extracted one or more indices to a threshold value. In some embodiments, the one or more indices are extracted from one or more planes of the signal. In some embodiments, the indices are extracted from the time axis, the frequency axis, the intensity axis, or any plane comprising two or more of the time axis, the frequency axis, the intensity axis.

In some embodiments, the method comprises calculating one or more deviations of the indices. In some embodiments, the one or more deviations are indicative of periodicity in the sequence under evaluation.

In some embodiments, at step 108, the method comprises determining a presence of a periodicity within the received sequence under evaluation based, at least in part, on a deviation of the at least one index from a threshold value. In some embodiments, the method comprises identifying the periodicity within the sequence based on the type of index and/or the magnitude of the deviation of the index from the threshold value. In some embodiments, the method comprises calculating the threshold value for the one or more indices. In some embodiments, the threshold value is a maximal or minimal value in relation to the sequence under evaluation. In some embodiments, the threshold value is predetermined and has a value that is independent from the sequence or the signal.

In some embodiments, the method comprises favoring periodic classifications of a sequence. In some embodiments, the algorithm is set to avoid an incorrect classification of a sequence lacking randomness by favoring periodic classifications of a sequence. In some embodiments, the method comprises classifying the sequence as random or as lacking randomness. In some embodiments, a sequence comprising one or more periodicities is classified as lacking randomness.

In some embodiments, the method comprises generating data in the form of one or more of a graph and a numerical representation of the signal. In some embodiments, the method comprises marking the one or more periodicities of the signal within the data. In some embodiments, the method comprises outputting the data. In some embodiments, the method comprises outputting an estimated value of a degree of randomness of the sequence. In some embodiments, the degree of randomness is based, at least in part, on the periodicities. In some embodiments, the degree of randomness is based, at least in part, on the number of periodicities and the relative positions of the periodicities. In some embodiments, the degree of randomness is based, at least in part, on the one or more indices and/or the deviation of the indices from the threshold value. In some embodiments, the algorithm favors labeling portions of the sequence or signal as periodic rather than random.

In some embodiments, the method comprises applying a correction function to one of the signal and the sequence. In some embodiments, the correction function is configured to alter the sequence. In some embodiments, the method comprises altering the sequence such that the periodicity is eliminated. In some embodiments, the method comprises altering the sequence such that if the algorithm is applied to the altered sequence, the outputted data will include a higher degree of randomness of the sequence and/or less periodicities. In some embodiments, a degree of randomness may be expressed as a fraction, such as a percentage. In some embodiments, the degree of randomness is expressed as a score on a specified scale.

### Statistical Tests and Randomization Algorithms

As described in greater detail elsewhere herein, sequences that are obtained from RNGs are commonly checked to verify randomness or presence of bias in the sequence. Verifying a randomness of a sequence is commonly done using statistical tests that are designed to check whether the given sequence lacks randomness. Once bias is discovered, ‘bleaching’ or ‘whitening,’ i.e., the process in which feedback is provided to the RNG in order to correct the sequence, is applied. Many of the methods used for correcting sequences are not completely random. Additionally, these methods usually do not depend on the test algorithm which outputted the tested sequence.

There is a great variety of statistical tests which are used to check the quality of a random number generator (referred to herein as quality tests of random number generators). The quality tests are not meant to mathematically prove whether the sequence that the generator produces is random, but to find vulnerabilities in the generator that may indicate poor randomness. The quality tests are applied to an inputted sampling sequence of an output of a random number generator. The sampling sequence is inputted in the form of bits. Each statistical quality test determines whether the inputted sequence contains certain predictable characteristics in a true random sequence. Such a test result or experiment is not deterministic but probabilistic.

For example, a true random sequence should contain bits of zero and one at approximately even distribution. If the sequence does not meet this requirement, it can be said that the generator that created the sequence fails experimentally. Additionally, if a bit number (one or zero) has a certain predetermined divergence rate, it can be said that the random sequence is “accepted,” meaning that its claim of randomness is not rejected. Even if the sequence successfully undergoes a given statistical test, it is not absolute proof of its randomness but more than a probabilistic confirmation.

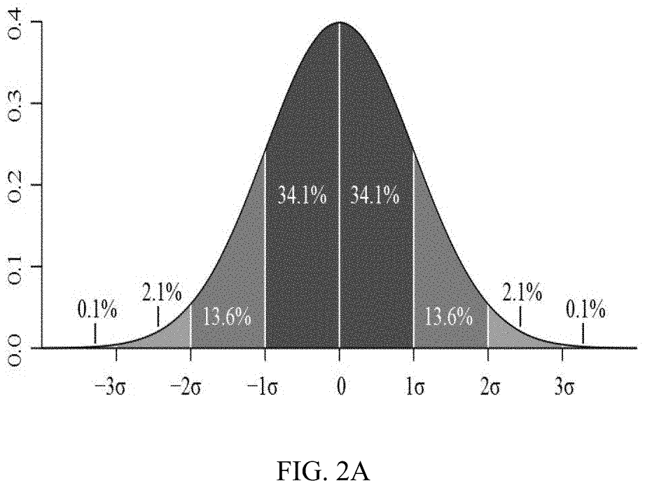

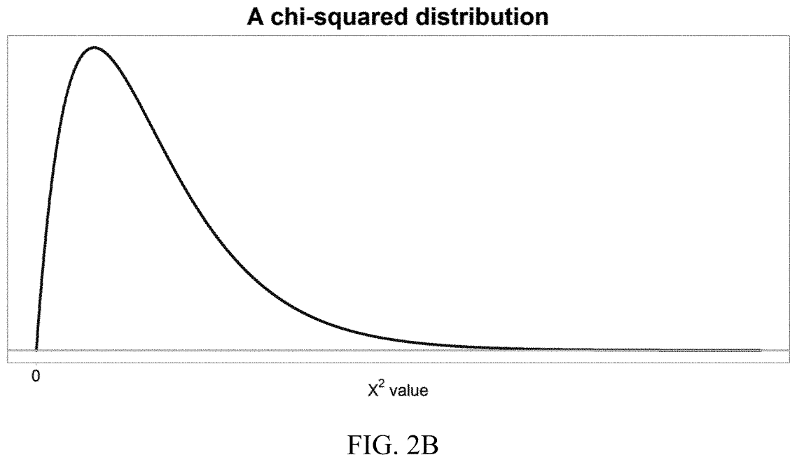

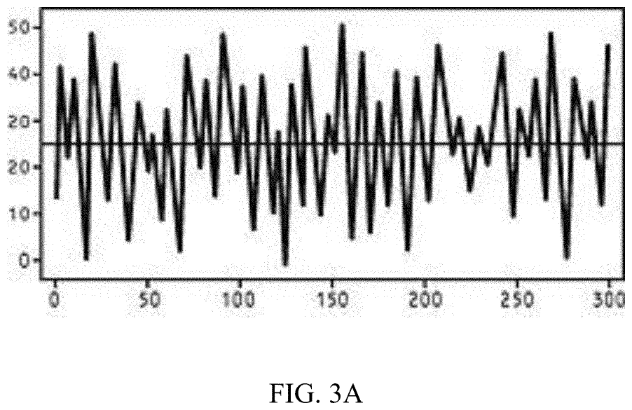

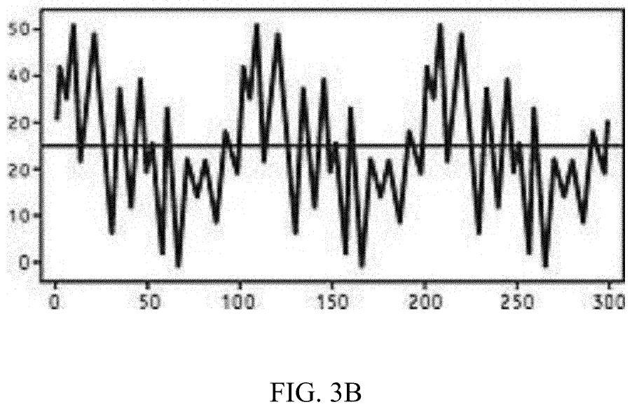

Reference is made to FIGS. 2A and 2B, which are schematic illustrations of the standard normal distribution and the chi square distribution. Most statistical tests are based on normal distribution and chi square distribution (X²). The normal distribution comprises the sum of a large number of independent random variables with identical expectation and variance. A random variable X has a normal distribution if its density function is of the form:

$$f ( x ) = \frac{1}{σ \sqrt{2 π}} exp ( \frac{- {( x - μ )}^{2}}{2 {σ}^{2}} )$$

It's been marked X˜N(μ, σ²). In the case when X˜N(0,1) a “standard” normal distribution is received in the form:

$$f ( x ) = \frac{1}{\sqrt{2 π}} {e}^{- \frac{{x}^{2}}{2}}$$

The distribution described in above is also called the “bell curve” due to the fact that the function graph is symmetrical with respect to the y axis, which gives a bell shape. The transition from the normal distribution of X˜N(μ, σ²) into a standard normal distribution is Z=(X−μ)/σ.

The chi square distribution X² with v number of degrees of freedom, occurs when sums of squares of v random independent variables have standard normal distribution.

The chi square distribution X² can be used in order to represent the degree of correlation between observed event frequency and estimated frequency under some probabilistic (hypothesis) assumption. The function of chi square distribution is in the form:

$$f ( x ) = \frac{1}{Γ ( v / 2 ) {2}^{v / 2}} {x}^{( \frac{v}{2} ) - 1} {e}^{- x / 2}$$

For x greater than zero the F(t) is called gamma function defined for t greater than zero in the form:

Γ(t)=∫₀^{∞}x^{t-1}e^{-x}dx

If X is a random variable with chi square distribution X² with v number of degrees of freedom, so P(X>x)=α. In other words, α represents the probability which X exceeds the expected value at x.

There are tables of chi square distribution values that can be used as a source for comparison. In the case of a standard normal distribution, when X˜N(0,1) it is said that the variable has a chi square distribution with one degree of freedom. A statistical experiment is a process that is based on values observed in one or more random variables, confirming a statistical hypothesis called the null hypothesis (H₀) that represents an argument about the distribution of variables or variables according to their significance level a. A significance level represents the probability that the null hypothesis will be accepted or rejected (also contrary to its correctness).

A condition where the null hypothesis is rejected despite being correct (when α value is too high) is called a “Type 1 error”. Type 2 error can occur when the significance level is too low, so there is a danger that the hypothesis will be accepted despite being incorrect, i.e. in this case the sequence will be considered random even though it is not.

The experiment is conducted with a statistical “data” which is a function of sampling elements (such as the number of zeros or ones in the sample). The figure should correspond to the normal distribution or chi squared of a true random sequence. The given values are compared with predetermined values. For example, if X fits to the chi square distribution if v degrees of freedom and the statistical data is known for the experiment, the results should comprise higher values than in the case of lacking randomness.

In some embodiments, the experiment comprises determining a “threshold” value x_{α} by a predetermined statistic (usually following true random values experiments) and calculating α=P(X_{α}). If the result of the given experiment is less than this value, then the sequence fails the test. In a similar way, the a values for each specific experiment are calculated and tested to see if the experiment result is less than this value. If in all cases the result is high, the sequence can be accepted as random. Of course, a low percentage of results should be taken into account, even in the case of a true random sequence that may be lower than the set thresholds, which is indicative of poor randomness. Determining threshold values is a difficult task, threshold values are usually set empirically.

Six basic statistical tests (that are listed in the Handbook of Applied Cryptography) are listed below. In the tests described, s=s₀, s₁, s₂, . . . , sₙ₋₁ is a series of bits in length n. The number of bits, n, needs to be large, for example, between 10³ to 10⁶ (million bits). The significance level is set here α=0.5 (other values are possible but require threshold values). An example of the percent values of normal distribution as expected from random variable behavior:

| | | | | | | | | |
|---|---|---|---|---|---|---|---|---|
| α | 0.0005 | 0.001 | 0.0025 | 0.005 | 0.01 | 0.025 | 0.05 | 0.1 |
| x | 3.2905 | 3.0902 | 2.8070 | 2.5758 | 2.3263 | 1.9600 | 1.6449 | 1.2816 |

For example, at the entrance α=0.05 and x=1.6449. The meaning is that if X as a standard normal distribution, then X exceeds the value 1.6449 at this point in about five percent of cases.

### Mono Bit Test

A two-way test designed to verify that the number of bit instances ‘1’ and ‘0’ is approximately the same, as expected from a random sequence. If n₀ and n₁ represents the bits “0” and “1” respectively then the formula is:

$$\frac{{( {n}_{0} - {n}_{1} )}^{2}}{n}$$

### Two Bit Test

The purpose of the test is to determine whether the number of pairs 00, 01, 10, 11 appearing in the sequence is approximately the same as expected from a random sequence. If n₀₀, n₁₁, n₁₀ and n₁₁ represent the pairs respectively then the formula is:

$$\frac{4}{n - 1} ( {n}_{0 {0}^{2}} + {n}_{0 {1}^{2}} + {n}_{1 {0}^{2}} + {n}_{1 {1}^{2}} ) - \frac{2}{n} ( {n}_{0}^{2} + {n}_{1}^{2} )$$

### Poker Test

In some embodiments, the poker test comprises dividing the s sequence into k parts, every part is in size of

$$[ \frac{n}{m} ]$$

bits when m fulfilling

$$[ \frac{n}{m} ] \geq 5 * ( {2}^{m} )$$

and the value nᵢ represents the number of instances of the i part. The poker test checks whether the number of all occurrences in the sequence is approximately the same as the expected number from a random sequence using the formula:

$$\frac{{2}^{m}}{k} ( {\sum }_{i = 1}^{{2}^{m}} {n}_{i}^{2} ) - k$$

Poker Test is the inclusion of Frequency Test, except that the poker test checks frequency of subsets greater than 1.

### Runs Test

The purpose of the test is to determine whether the number of runs (zero or one sequential sequences) of different lengths appears sequentially at the frequency expected from the random sequence. A run of ones is called a block, while a run of zeros is called a gap. The number of runs in length i in a sequence in length n should be

$$\frac{n - i + 3}{{2}^{i}} + 2$$

if Bᵢ and Gᵢ represent the runs of zeros and ones respectively, so the test's formula is:

$${\sum }_{i = 1}^{k} \frac{{( {B}_{i} - {e}_{i} )}^{2}}{{e}_{i}} + {\sum }_{i = 1}^{k} \frac{{( {G}_{i} - {e}_{i} )}^{2}}{{e}_{i}}$$

While

$${e}_{i} = \frac{n - i + 3}{{2}^{i + 2}}$$

and k represents the longest run that makes eᵢ≤5.

### Auto-Correlation Test

The purpose of the test is to look for correlation (correlation level) between overlapping segments of the sequence. If d is a lower value than

$$[ \frac{n}{2} ]$$

number or bits in s Which are not suitable for indentation, d is A(d)=Σᵢ₌₀^{n-d-1}sᵢ+s_{i+d}. The auto correlation function is:

$$2 ( A ( d ) - \frac{n - d}{2} ) / \sqrt{n - d}$$

### The Universal Test of Maurer

Ueli M. Maurer published a universal test for a random pseudo-generator that, unlike other tests, is able to detect any significant statistical deviation of the generator's output from a true random output. The idea is based on the fact that if the generator output can be shifted (without loss of information) significantly, the output is not random. Instead of trying to actually compress the output, the Maurer algorithm tries to estimate the length of the sequence being tested after compression. The main disadvantage of the algorithm required is sampling of output much longer than required in the tests described above. The idea of Maurer algorithm is as follows: Divide the sequence s into non-overlapping segments each with bit size L, where the total number of chunks should be Q+K. The value of Q should be lower than 10*2^{L}−1 and K should be lower than 1000*2^{L}. The value bᵢ represents the integer whose binary representation is the chunk i in the range [1, Q+K]. Produce a table T with Q+K entries, in the Q first entries place the block number bᵢ last to be appeared, meaning that for i from 1 to Q we place T[bᵢ]=i while i represents the number of chunk bᵢ in the sequence. K The remaining entries are used to calculate the statistics as follows. For each block i from Q+1 to Q+K, i was placed at the entrance T[bᵢ]. The test includes summarizing the distances for all blocks, that is, the number of blocks from the last instance of the said block to the current block and calculating the logarithm at the base 2 of the final sum and divide by K. As follows:

$$\frac{1}{K} {\sum }_{i = Q + 1}^{Q + K} {log}_{2} ( i - T [ {b}_{i} ] )$$

In some embodiments, the disclosed algorithm replaces the national institute of standards and technology (NIST) tests 6-8 (as known in the art) with another type of test that does all three as one test.

The NIST test set is adapted only for checking the quality of randomness of the information chain and not for correcting it. Further, the NIST tests are adapted for checking stationary signals and not dynamic signals.

A potential advantage of the method, system, and computer program product of the present disclosure is in that the method, system, and computer program product of the present disclosure can replace at least the NIST tests 6-8 with another type of test that does all three as one test. Moreover, the NIST test set is used for checking the quality of randomness of the information chain and not for correcting it. Further, the NIST tests set is usable for checking stationary signals but fails to identify lack of randomness in dynamic signals. Moreover, the method, system and computer readable program disclosed herein in addition to being capable of identifying lack of randomness in dynamic signals, is also capable of locating the chunks in the tested signal that contain non-random signal, thereby allowing fixing that signal.

### Estimation of Degree of Randomness

In some embodiments, the method disclosed herein offers a new way of estimating the degree of randomness of a sequence. In some embodiments, the method performs a two-dimensional analysis of the time and frequency planes of the sequence. In some embodiments, the method determines if the signal is random in a non-stationary signal. In some embodiments, the method detects the positions of periodic segments in the sequence, and to correct these segments. Therefore, in some embodiments, the method allows developing an algorithm wherein, for a tested sequence, the result of the test comprises the randomness of the sequence, the sequence identification, and signal correction. In some embodiments, the disclosed method improves the degree of randomization of a sequence produced by a generator (RNG).

In some embodiments, the algorithm is based on an application of one or more transformations to a received random sequence of bits, e.g., a Wigner Distribution function and a Generalized Gaussian Distribution function. In some embodiments, a detection algorithm is used on the received signal after applying the transformations. In some embodiments, the detection algorithm outputs an output comprising a signal that marks regions suspected of being periodic within the sequence. Therefore, for a sequence that was found to have one or more periodic sections, the periodic sections can be repaired or removed.

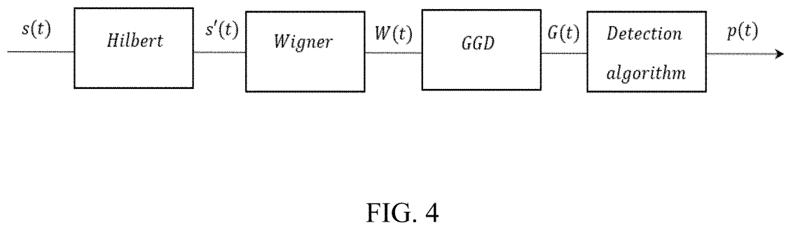

Reference is made to FIG. 4, which shows an algorithm block diagram, in accordance with some embodiments of the present disclosure. In some embodiments, for a sequence under evaluation, a vector of values is obtained in the time plane, using Wigner transform to move to a quadratic matrix which represents the sequence behavior in the time and frequency planes. In order to be able to detect changes in the time plane, generalized Gaussian distribution (GGD) is used. In some embodiments, applying a GGD comprises an operation that reverses the matrix into a vector, where the values of the vector are a new parameter that characterizes the signal behavior in the time plane. In some embodiments, it is possible to activate the detection algorithm of the periodic sections of the sequence.

Wigner function is the Fourier transform of the autocorrelation of a signal, wherein the continuous expression sequence is:

$${W}_{x} ( t , ω ) = {\int }_{- ∞}^{∞} [ x ( t + \frac{τ}{2} ) {x}^{*} ( t - \frac{τ}{2} ) {e}^{- j ω τ} ] d τ \qquad ( 1 )$$

When resetting the variables, the expression can be written:

$${W}_{x} ( 0 , 0 ) = {\int }_{- ∞}^{∞} [ x ( \frac{τ}{2} ) {x}^{*} ( - \frac{τ}{2} ) ] d τ \qquad ( 2 )$$

After replacing a variable, it can be written like:

$$( d τ = 2 d {τ}^{′} , \frac{τ}{2} = {τ}^{′} )$$

Wₓ(0,0)=2*∫_{-∞}^{∞}[x(τ)x*(−τ)]dτ (3)

In order to perform the transformation from continuous time to discrete time, the desired function x(t) is multiplied by the sinc function while the time variable from sample to sample is T.

$$x ( t ) = {\sum }_{n = - ∞}^{∞} x ( n T ) \frac{sin π ( t / T - n )}{π ( t / T - n )} \qquad ( 4 )$$

After the signal multiplied by itself and the sampling is performed, the signal multiplier is expressed in the Dirac functions line while k=n.

$${\int }_{- ∞}^{∞} \frac{sin π ( t / T - k )}{π ( t / T - k )} * \frac{sin π ( t / T - n )}{π ( t / T - n )} dt = T {δ}_{k , n} \qquad ( 5 )$$

Using equations 3 and 5, equation 6 can be written:

Wₓ(0,0)=2TΣ_{k=-∞}^{∞}x(kT)*x*(−kT) (6)

In order to move into an expression with time and frequency variables—the Wigner function can be used, while φ is the moving operator in time and μ is the modulation operator:

W_{φx}_{_{−t}}_{,μx}_{_{−ω}}(0,0)=Wₓ(t,ω) (7)

The use of equation 7 allows writing the expression used for discrete time:

Wₓ(nT,ω)=2TΣ_{k=-∞}^{∞}x[(n+k)T]*x*[(n−k)T]e^{—j2ωkT} (8)

Transformation into a discrete time requires the use of the Hilbert transformation, this action is needed in order to avoid the aliasing phenomenon of the signal itself. The transformation makes the entering signal to analytic, so that in the negative frequency range (−π<θ<0) the signal is resetting.

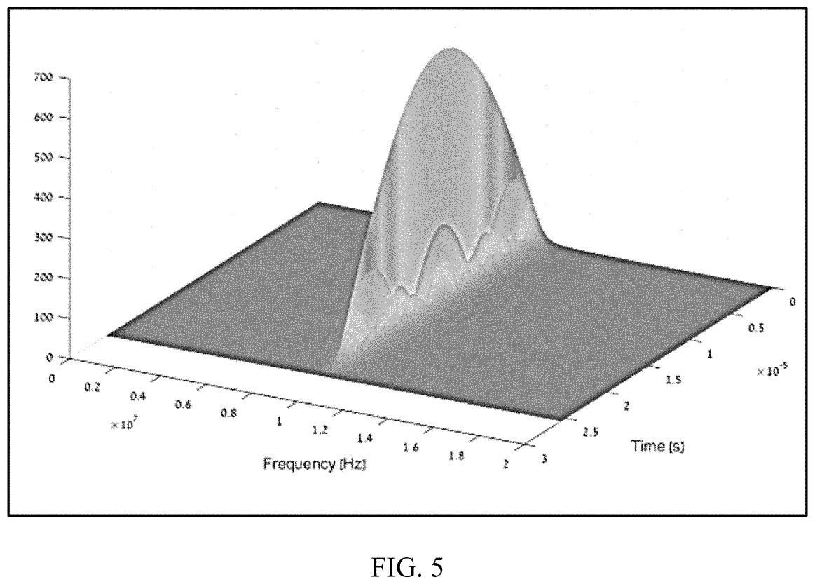

Reference is made to FIG. 5, which shows the periodic signal for f=10 [MHz]. In some embodiments, such as depicted by FIG. 5, the result of the function periodic signal f=10 [MHz], cosine comprises a three-dimensional image is obtained, including the time, the frequency and the intensity.

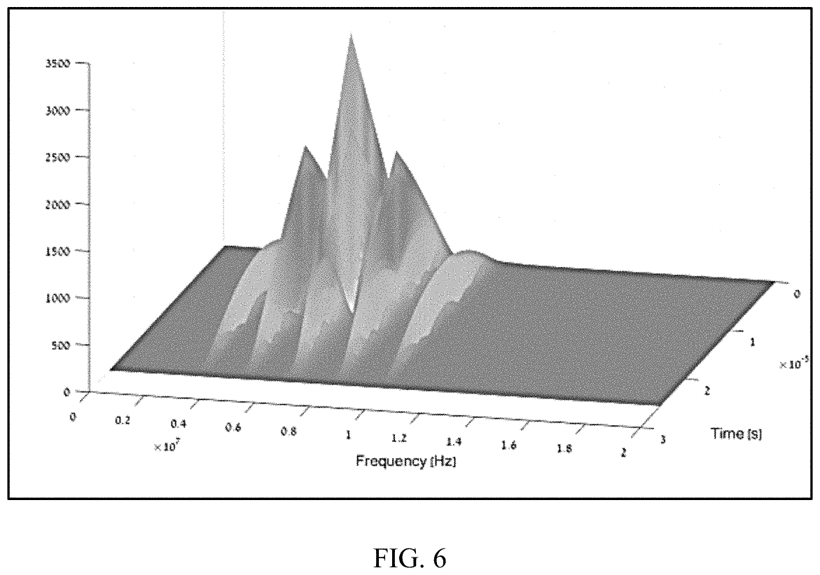

Reference is made to FIG. 6, which shows the periodic signal for f₁=3 [MHz], f₂=7 [MHz], and f₃=10 [MHz]. In some embodiments, for three similar signals having different frequencies, which are inputted into the function, an image depicted in FIG. 5 is received. In some embodiments, the result shows additional signals at frequencies that do not exist in the signal; these parts are due to the cross-correlation of the signals, meaning that when we enter the function with many signals on one side the image that is obtained will be difficult to detect the frequencies that do exist, but on the other hand it can be observed that the intensity climbs to high values (in this case when there are three similar signals with different frequencies that exist throughout the signal duration—the intensity value climbs to a height of 3500 as opposed to a single signal reaching 700, for a signal with equal number of samples). Therefore, in some embodiments, it can be predicted that the random signal detection will be performed by examining the signal intensity.

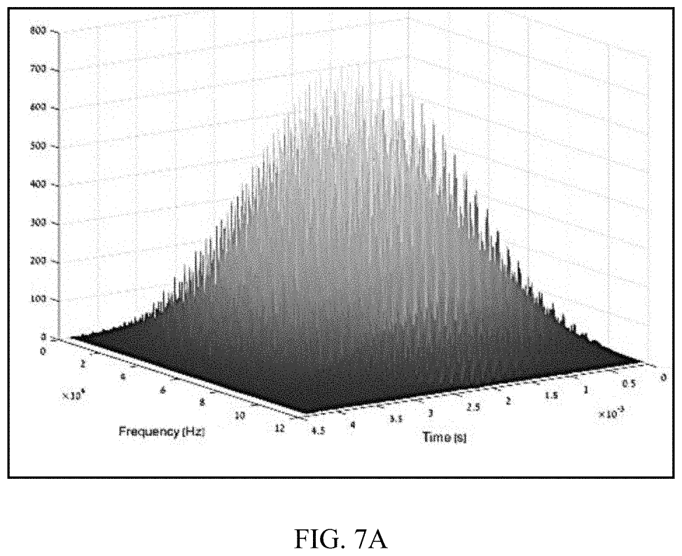

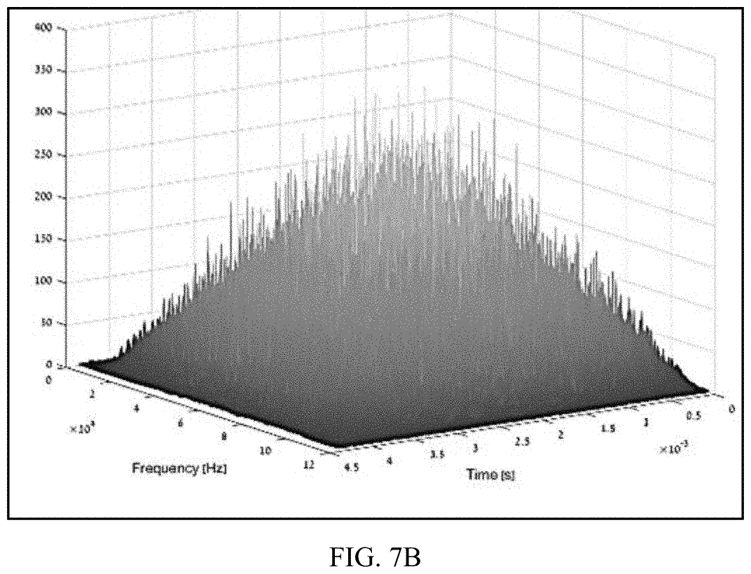

Reference is made to FIGS. 7A and 7B, which show two random sequences.

FIG. 7A shows a sequence with periodicity. It can be seen in FIGS. 7A and 7B that the image obtained after inserting a completely random signal (FIG. 7A) versus a random signal with periodicity (FIG. 7B). The signal intensity in this case is double the size when there is a period in the signal.

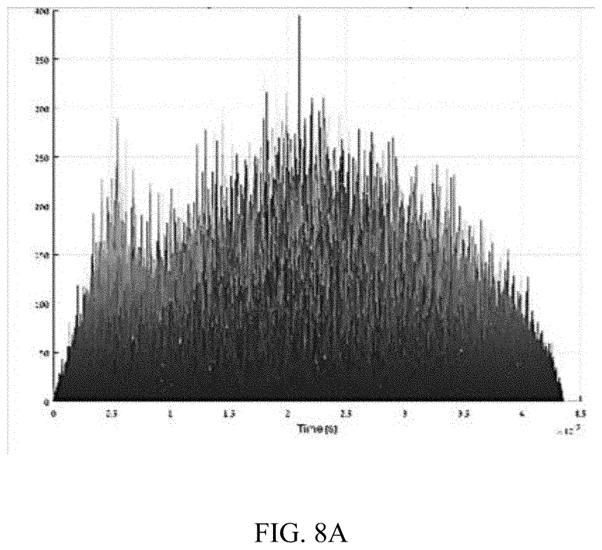

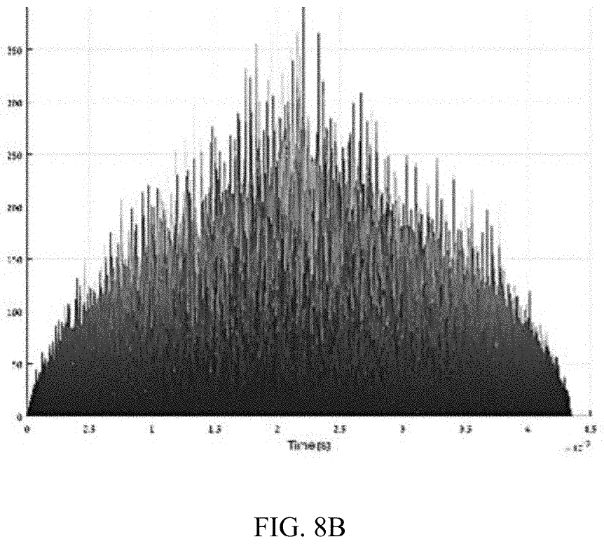

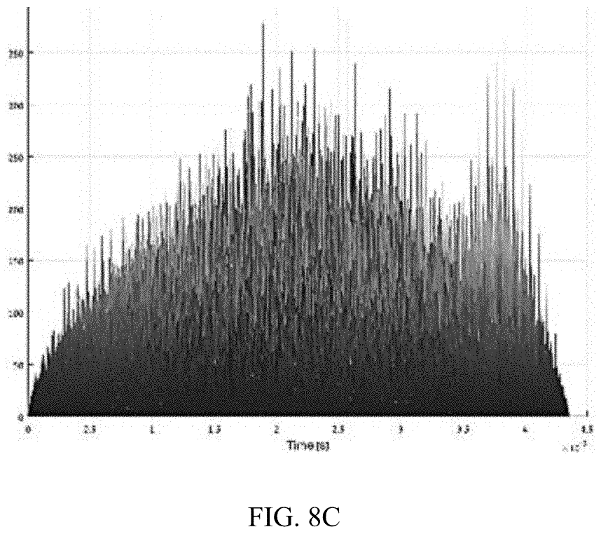

Reference is made to FIGS. 8A, 8B, and 8C, which show exemplary random sequences with a periodic section. FIGS. 8A, 8B, and 8C show the sequences at the time plane, the location of a periodic segment at the beginning of the sequence (FIG. 8A), middle (FIG. 8B) and end (FIG. 8C).

In some embodiments, using the Wigner function allows for the detection of changes in the time plane. A demonstration of this can be seen in FIGS. 8A, 8B, and 8C, which show the timeline and intensity. In each case, the periodic segment is inserted at a different location—but through the matrix, the location of the periodic segment can be traced by the change in the intensity.

Table 1 below shows a concentration of results for comparing the results of the DFT test with the Wigner test. For this purpose, eight sequences were constructed in a different structure (number of cycles, cycle length and segment position). Each structure was tested in three different lengths of sequence 1024, 2048 and 4096. From the results it can be seen that the DFT test (the existing method so far) with relation to Wigner (the disclosed method) cannot detect a non-stationary sequence.

After running the Wigner function, an algorithm was used to look for various measures of intensity height. After performing a model on random sequences, it can be determined that, when an exception is detected—this indicates periodicity of the signal. It should be noted that the cases examined are cases of ‘high periodicity’ (number of large periods or length of long periodic section). Details of the indices can be seen at the bottom of the table.

TABLE 1
Comparison between the DFT test and Wigner

| Number of | Length of | DFT | | WIGNER | | | | |
|---|---|---|---|---|---|---|---|---|
| samples | samples | P_value | Random | Power | Distance | Density | Highest | Random |
| 1 | 1024 | 1.2168e−04 | no | 0.9-1 | 0.625 | 0.51 | 1208 | no |
| 2 | 1024 | 0.8364 | yes | 0.9-1 | 0.72 | 0.56 | 3611 | no |
| 3 | 1024 | 0.4559 | yes | 0.7-0.8 | 0.2 | 0.78 | 18 | no |
| 4 | 1024 | 0.6464 | yes | 0.7-0.8 | 0.15 | 0.88 | 6 | yes |
| 5 | 1024 | 0.4913 | yes | 0.8-0.9 | 0.25 | 0.79 | 19 | no |
| 6 | 1024 | 0.4913 | yes | 0.7-0.8 | 0.35 | 0.9 | 19 | no |
| 7 | 1024 | 0.6881 | yes | 0.8-0.9 | 0.37 | 0.83 | 36 | no |
| 8 | 1024 | 0.0665 | yes | 0.8-0.9 | 0.44 | 0.76 | 33 | no |
| 9 | 2048 | 7.1886e−12 | no | 0.9-1 | 0.6 | 0.6 | 3282 | no |
| 10 | 2048 | 0.7151 | yes | 0.9-1 | 0.76 | 0.5 | 9182 | no |
| 11 | 2048 | 0.6881 | yes | 0.7-0.8 | 0.24 | 0.77 | 13 | no |
| 12 | 2048 | 0.1215 | yes | 0.7-0.8 | 0.2 | 0.61 | 7 | no |
| 13 | 2048 | 0.207 | yes | 0.7-0.8 | 0.26 | 0.91 | 48 | no |
| 14 | 2048 | 0.3304 | yes | 0.7-0.8 | 0.15 | 0.91 | 13 | yes |
| 15 | 2048 | 0.0027 | no | 0.8-0.9 | 0.23 | 0.84 | 43 | no |
| 16 | 2048 | 0.0167 | yes | 0.8-0.9 | 0.23 | 0.8 | 51 | no |
| 17 | 4096 | 1.3041e−21 | no | 0.9-1 | 0.65 | 0.62 | 6346 | no |
| 18 | 4096 | 0.5281 | yes | 0.9-1 | 0.7 | 0.51 | 24,527 | no |
| 19 | 4096 | 0.1687 | yes | 0.7-0.8 | 0.25 | 0.72 | 4 | no |
| 20 | 4096 | 0.0031 | no | 0.7-0.8 | 0.15 | 0.3 | 11 | no |
| 21 | 4096 | 0.2758 | yes | 0.8-0.9 | 0.28 | 0.92 | 84 | no |
| 22 | 4096 | 0.0963 | yes | 0.7-0.8 | 0.21 | 0.93 | 19 | no |
| 23 | 4096 | 0.002 | no | 0.8-0.9 | 0.3 | 0.84 | 96 | no |
| 24 | 4096 | 0.2175 | yes | 0.8-0.9 | 0.24 | 0.81 | 124 | no |

Power: Describes the height of the samples after the function is activated on the signal. The size shown in the table indicates the high intensity of the measurements. In some embodiments, in order to obtain a random signal index, a maximum range of power must be obtained: power=0.7-0.8.
Distance: Describes the ‘distance’ equals to the number of samples between two samples with power 0.8. In some embodiments, in order to obtain a normalized range—the received value is divided by the number of samples of the sequence tested. In some embodiments, in the random signal the received distances are: dis=0.1-0.3.
Density: Describes a ratio of the number of samples above power of 0.75 in the central part of the matrix to their numbers in each matrix. In some embodiments, a high ratio is received for a random signal—meaning, most of the high samples are in the center of the signal den>0.87.
Highest: Describes the number of samples above power of 0.9. In a random signal, the received number are highest<15. (This measure was not normalized, so the number shown in Table 1 corresponds to 1024 length sequences).

In some embodiments, all the sequences listed in Table 1 are sequences with a high number of cycles, which means that these measures can only classify sequences with high cyclicity. Accordingly, in order to examine sequences with low cyclicity, another tool is needed. Accordingly, it can be concluded that the DFT test failed to identify the sequences in Table 1 as cyclic, whereas the Wigner test can be used in the algorithm as a stage that classifies high-cyclic sequences, wherein these sequences will be disqualified and will not move to the next stage of detection and repair.

In some embodiments, the parameters that influence a shape of the distribution include a variance, a mean, and a shape factor. In some embodiments, the shape factor is represented by a p parameter. In some embodiments, as p approaches infinity, a uniform distribution (straight line) is obtained, whereas the smaller p is the distribution of a sharper shape.

The shape parameter allows characterizing the matrix obtained after the Wigner function, so that each row or column in the matrix can be expressed by a single value. Thus, a vector is obtained which characterizes the time or frequency plane through the shape parameter, where in places where there is periodicity, the value of the shape parameter can be expected to change.

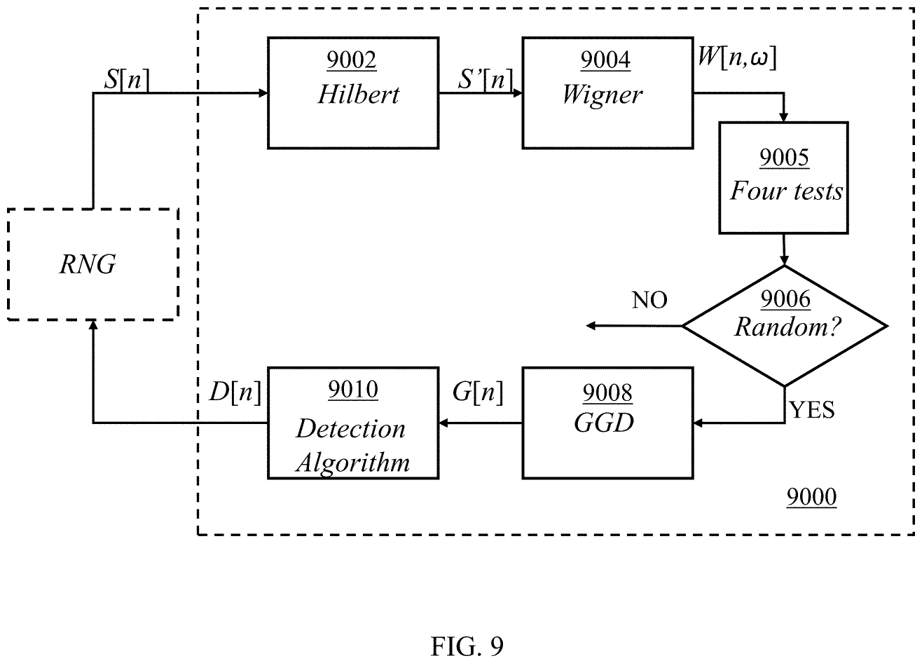

According to embodiments of the present invention a method for testing a signal for a desired level of randomness and for providing indications of location(s) in the signal where the level of randomness is too low and if the signal in these location(s) will be corrected, the randomness of the entire signal will be restored. Reference is made to FIG. 9, which is a schematic diagram depicting a system 9000 and a method for checking and providing correcting instruction of a signal supposed to be random, according to embodiments of the present invention. The functionalities listed herein below that are part of the operation of system 9000 may be performed, or carried out, by a single computer or computing unit or by several computing unit connected with each other. In some embodiments a computer readable storage may comprise code, in the form of a computer executable program(s), that when executed perform the functionalities of system 9000.

The input signal to system 9000 is s[n] which is the sampled output from the RNG with sample rate of fₛ, where T=1/fₛ and T is the sampling period (s(nT)→s[n]). Next, this signal (s[n]) is converted to an analytic signal with the help of the Hilbert transform 9002. Now, the analytical signal s′[n] is driven to the Wigner function 9004. The input to the Wigner function 9004 has to be an analytical signal in order to avoid the aliasing problem associated with the Wigner transform for non-analytical signals only. By using the Wigner function 9004 this vector is converted to a quadratic matrix W[n, ω] which represents the sequence behavior in the time and frequency domains. It should be emphasized that the NIST tests are for testing signals in a single domain—the time domain or the frequency domain. The output from the Wigner function in block 9004 is directed to undergo tests with respect to the “power”, “distance”, “density” and “highest” parameters of the received matrix at block 9005, as explained herein below in detail. After performing this test decision may be taken at decision block 9006 whether the incoming sequence has a high periodicity within the sequence or whether the repetitive sequence has a high length and should be announced as a non-random sequence (“NO” exit), or at this stage, no periodicity was yet detected within the sequence, hence the next step of the algorithm should be taken (“YES” exit). The meaning of a the NO decision may be interpreted as related to a signal in which the randomness quality is too low and therefore should not be corrected. If the algorithm does not detect at this stage a high periodicity within the sequence or a high length of a repetitive sequence at this point, the next step in the algorithm may be taken, which is the GGD function 9008. To detect randomness level in a dynamic signal, the GGD 9008 is being used as is explained herein below. The output from the Wigner function [24] is W[n, ω] and is given by:

W[n,ω]=fft(Rₛₛ[τ,n]) (9)

Where ω=2πf, f stands for the frequency, fft(.) is the Fast Fourier Transform on (.) and Rₛₛ[τ, n] is the Autocorrelation of s′[n] given by:

Rₛₛ[τ,n]=E[(s′[n]*s′*[n+τ])] (10)

where “*” is the multiplication operation, s′*[n] is the conjugate part of s′[n] and E[.] stands for the expectation operation.

This step is based on examining the changes in the shape parameter associated with the GGD function 9008.

Changes in the shape parameter of the GGD 9008 presentation, change the shape of the probability density function (PDF) of the given input sequence to the GGD 9008 which may have a Laplacian, or double exponential distribution, a Gaussian distribution or a uniform distribution for a shape parameter equal to one, two and infinity, respectively. Changes in the PDF of the tested input sequence to the GGD 9008 indicates that the input sequence is not random. The shape parameter allows to characterize the absolute values from the matrix obtained from the Wigner function 9004, so that each row or column in the matrix can be expressed by a single value. Thus, a vector that characterizes the time or the frequency domain through the shape parameter can be obtained. In the algorithm of system 9000, the time domain is in interest, therefore the shape parameter is calculated on each column (representing the frequency domain) in the matrix. The obtained vector will be denoted as G[n].

The pdf of the GGD presentation:

$$G G D ( x ; μ , σ , p ) = \frac{1}{2 Γ ( 1 + \frac{1}{p} ) A ( p , σ )} {e}^{-} {\vert \frac{x - μ}{A ( p , σ )} \vert}^{p} , x ∈ ℝ \qquad ( 11 )$$

$$\begin{matrix}A ( p , σ ) = [ \frac{{σ}^{2} Γ ( 1 / p )}{Γ ( 3 / p )} ] \\ {M}_{( p )} = \frac{{( E \vert X \vert )}^{2}}{E {X}^{2}}\end{matrix} \qquad ( 12 )$$

the reciprocal function of M(p) is known as generalized Gaussian function ratio (ggfr). Hence, the MME for σ and p may be obtained after solving the following:

$$\frac{1}{n} {\sum }_{i = 1}^{n} \vert {X}_{i} \vert = σ \sqrt{{M}_{( p )}} and \frac{1}{n} {\sum }_{i = 1}^{n} {\vert {X}_{i} \vert}^{2} = {σ}^{2}$$

After performing a model it is assumed that the function graph M(p) can be divided into 4 parts, in order to obtain an approximation by functions from which p can be extracted.

$${M}^{*} ( p ) = \{ \begin{matrix}{3}^{\frac{1}{2} * \frac{p - 6}{p}} {2}^{\frac{4 - p}{p}} if p ∈ [ 0 , 0.2771981 ) \frac{1}{2} \\ {a}_{1} {p}^{2} + {a}_{2} p + {a}_{3} if p ∈ [ 0.2771981 , 0.828012 ) \frac{1}{2} \\ \frac{{b}_{1} p}{1 + {b}_{2} p + {b}_{3} {p}^{2}} if p ∈ [ 0.828012 , 2.631718 ) \\ \frac{3}{4} - {c}_{1} {e}^{- {c}_{2} p + {c}_{3} {p}^{2}} if p ∈ [ 2.631718 , ∞ )\end{matrix} \qquad ( 13 )$$

Meaning, an expression to revalue the parameter p can be registered, while M*(p)=kᵢ:

$${p}^{*} ( {k}_{i} ) = \{ \begin{matrix}{2}^{ln \frac{27}{16} / ln \frac{3}{4 {k}_{i}^{2}}} if {k}_{i} ∈ [ 0 , 0.131246 ) \\ \frac{1}{2 {a}_{1}} ( - {a}_{2} + \sqrt{{a}_{2}^{2} - 4 {a}_{1} {a}_{3} + 4 {a}_{1} {k}_{i}} ) if {k}_{i} ∈ [ 0.131246 , 0.4 \; 48994 ) \\ \frac{1}{2 {b}_{3} {k}_{i}} ( {b}_{1} - {b}_{2} {k}_{i} - \sqrt{{( {b}_{1} - {b}_{2} {k}_{i} )}^{2} - 4 {b}_{3} {k}_{i}^{2}} ) if {k}_{i} ∈ [ 0.448994 , 0.6 \; 71256 ) \\ \frac{1}{2 {c}_{3}} ( {c}_{2} - \sqrt{{c}_{2}^{2} + 4 {c}_{3} ln ( \frac{3 - 4 {k}_{i}}{4 {c}_{1}} )} if {k}_{i} ∈ [ 0.671256 , 0.75 )\end{matrix} \qquad ( 21 )$$

where a₁=−0.535707356, a₂=1.168939911, a₃=—0.1516189217, b₁=0.9694429, b₂=0.8727534, b₃=0.07350824, c₁=0.3655157, c₂=0.6723532, c₃=0.033834.

And kᵢ can be calculated by:

$${k}_{i} = \frac{{( E \vert {\tilde{W}}_{i} \vert )}^{2}}{E [ {( \vert {\tilde{W}}_{i} \vert )}^{2} ]}$$

where \tilde{W}ᵢ is the i-th column (representing the frequency domain) in the matrixW[n, ω]. Based on the above the vectorG[n] can be defined:

G[n]=[p(k₁),p(k₂),p(k₃) . . . p(k_{N})]

where N is the length of the tested input sequence.

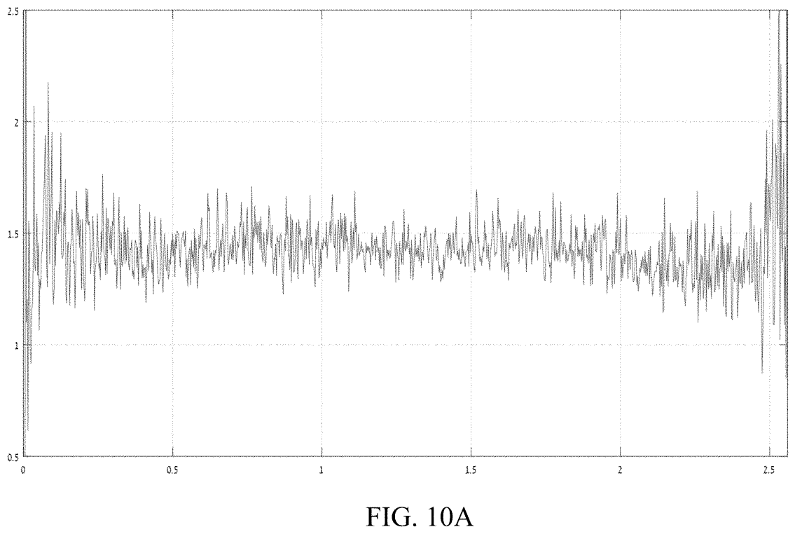

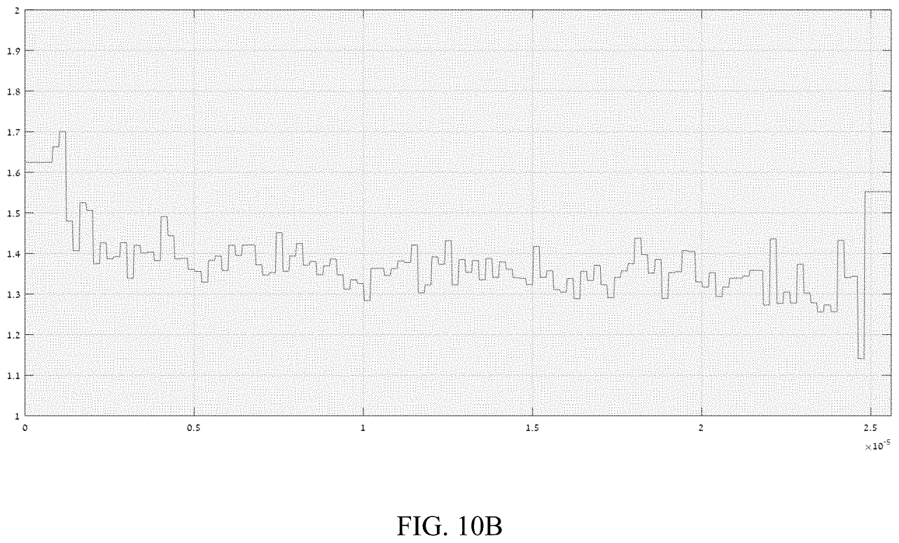

Reference is made to FIG. 10A, which shows an exemplary resulting vector image after GGD activation (time plane) for a random input sequence of length 1024.

Using the GGD function on the received result from the Wigner function which allows to simplify the result (e.g., an example of the received signal as depicted in FIG. 9), and therefore: it is better to determine whether the signal is random (even in cases where the signal is not stationary) and it is possible to trace the periodic segment in the sequence.

Furthermore, the cases examined so far have been cases where there is high periodicity, but when the number of periods in succession decreases to 2 or a short sequence (periodic segment of 100 samples out of 1024) from the result of the Wigner function there is difficulty in identifying. Meaning, the use of GGD allows for more complex cases.

The signal on which the detection algorithm is applied is the vector describing the distribution of the shape parameter in the time plane, because the purpose is to find the location of the periodicity in time. Starting from this stage, the algorithm is divided into 2: Classification of the sequence as random or cyclical and after determining that there is periodicity, periodicity detection is performed.

Reference is made to FIG. 10B, which shows an exemplary shape parameter signal after execution signal averaging to signal G[n] of Figure Q. In order to simplify the classification or detection phase, action of ‘smoothing’ of the signal was preformed, meaning the performance of each number of measurements was performed, for example, such as depicted by FIG. 10.

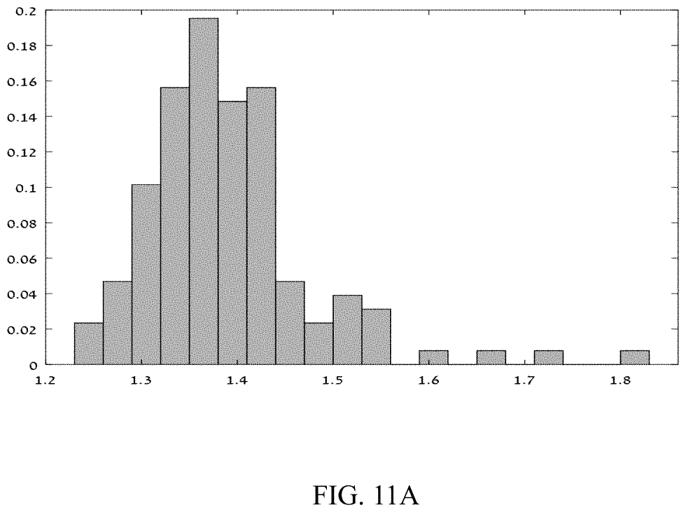

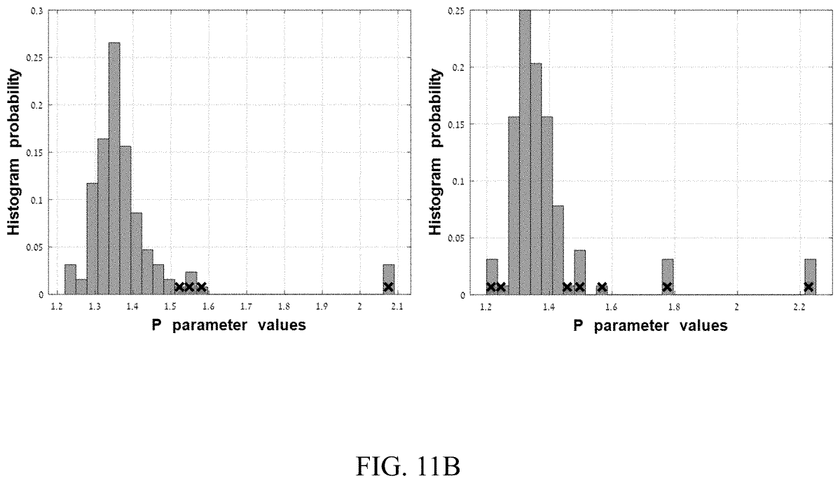

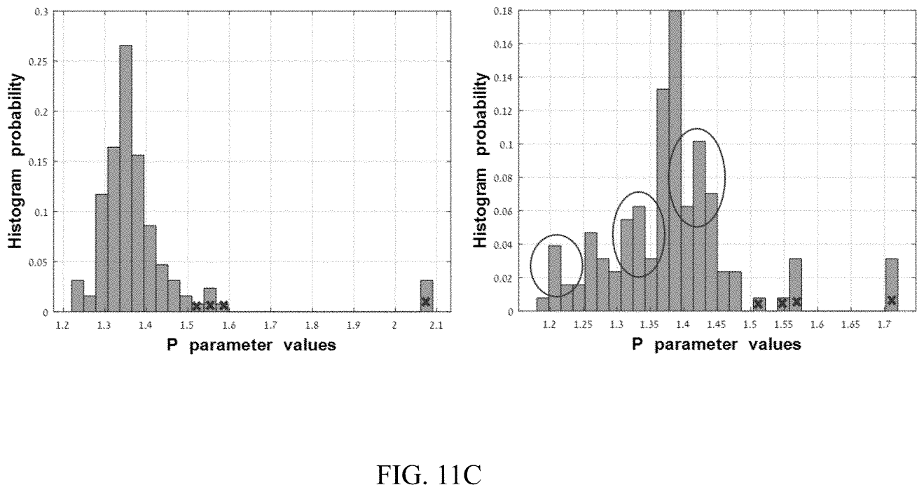

Reference is made to FIG. 11A, which shows an exemplary histogram operation on the signal of the shape parameter. To perform the first step of sequencing, the histogram function was used (for example, the signal obtained in FIG. 11A), which describes the distribution of the appearance of values of the shape parameter. In order to make the distinction, a model was performed on random sequences and 6 indices were determined, deviation of which indicates a signal with periodicity. The sequence classification criterion is set so that it is preferable to classify a random sequence as periodic rather than vice versa, because the algorithm will fix the suspicious regions. Unlike other tests that return a statistical value that determines whether a sequence can be used, the disclosed algorithm performs a correction (so even a random signal correction does not detract from the result).

The following are the tests that can be performed on the signal to determine the indices:
Test 1: Checks whether the maximum height of a P parameter is at the center of the probability histogram graph and the width of the graph is greater than 0.2. If the conditions are not met—the signal will be marked as a periodic signal.
Test 2: Checks if there is more than one peak of a P parameter in the graph (the test looks for the 2 highest values in the signal, when their difference should be less than 15%, and they have at least one bin). If there is one peak, the signal is marked as periodic.
Test 3: Checks whether the maximum bin height of a P parameter in time is between 1.28 and 1.4 (x-axis). If it is outside of these boundaries the signal is marked with periodicity.
Test 4: Checks whether there is a maximum value of the bin of a P parameter is above 0.25, if the signal is also marked as a periodic signal. (This indicates that there is too much concentration around a certain frequency in the signal).
Test 5: Checks the position of the maximum value of the bin of a P parameter between the time plane and the frequency plane (a random signal is obtained from a 3D Gaussian form, when there is no match between the frequency plane and the time plane in the shape parameter—this indicates periodicity in the signal). If there is no match the signal is marked as periodic signal.
Test 6: This test checks two conditions concerning the heights of the bins of a P parameter. First, it checks if a bin can be found with a height lower than 0.05. Next, it checks whether a bin can be found with a height above 0.2. If no bin is left with a height lower than 0.05 and a bin is found with a height above 0.2, the sequence is announced as a non-random sequence. This test is performed in the time domain. An example for this test can be seen in FIG. 11B to which reference is now made, where at the right graph the result for a non-random input sequence in which all the bins that were already deleted before entering into this test were marked. As seen in FIG. 11B there is a bin with a height above 0.2 and there is no bin with a height lower than 0.05. Thus, the result presented in the right graph of FIG. 11A, corresponds to a non-random sequence.
Test 7—The probability density function (PDF) should increase monotonically towards the center bin (or to the bin with the maximum height) of the PDF and decrease monotonically from the center bin (or from the bin with the maximum height) downwards. If there is a 40% decrease in the height of a bin with the bin before it, the tested sequence is announced as a non-random sequence. An example for this test can be seen in FIG. 11C to which a reference is now made, where we have at the right figure the result for a non-random input sequence where we have circled the places where the decrease in the height of 40% was found. Bins that were already deleted in the early stage of the test are marked.

The second step in the detection algorithm is to find the periodic part in the tested input sequence. For this purpose, three different kinds of averages may be applied on the tested averaged vectorG[n]. The three different kinds of averages are as follows:
The average of the whole averaged vectorG[n] (except for some samples at the beginning and at the end) is carried out here. Thus, one average value is obtained. In the following, we denote this kind of averaging as “Average number 1”.
The averaged vector G[n] (except for some samples at the beginning and at the end) is divided into 3 parts (40%-20%-40%) and then the average operation is carried out on each part. Thus, here we have three average values. In the following, we denote this kind of averaging as “Average number 2”.
The averaged vector G[n] (except for some samples at the beginning and at the end) is divided into 3 parts (25%-50%-25%) and then the average operation is carried out on each part. Thus, here we have three average values. In the following, we denote this kind of averaging as “Average number 3”.

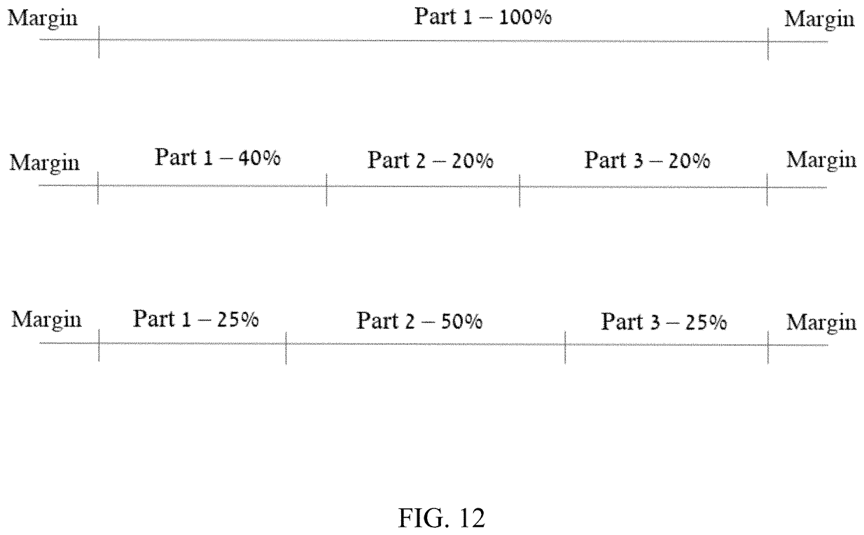

FIG. 12, to which reference is now made, presents three different kinds of averages carried out on a tested averaged vector G[n], where “Margin” means that at the beginning and at the end of the averaged tested G[n] no averaging operation is carried out. For the case of a 1024, 2048 and 4096 length sequence, the margin on each side is 32 samples, 64 samples and 128 samples respectively. In order to declare an area to be suspicious of not being a random sequence, the values of the averaged vector G[n] may be compared to the values of Average number 1, Average number 2 and to Average number 3. In general, if the values of the averaged vector G[n] are above or below the average number (Average number 1±ε₁, Average number 2±ε₂, Average number 3±ε₃ where ε₁, ε₂ and ε₃ are predefined values) for some tested values that come in sequence, a suspicious place is declared.

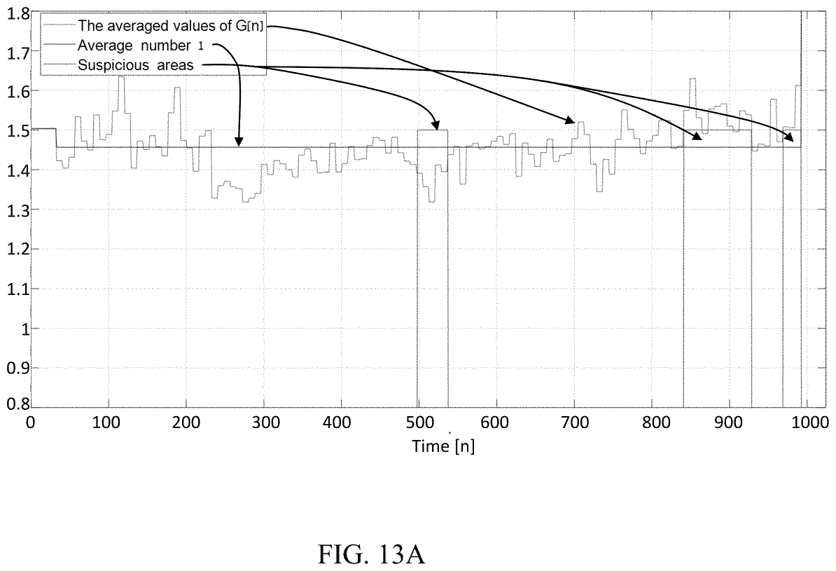

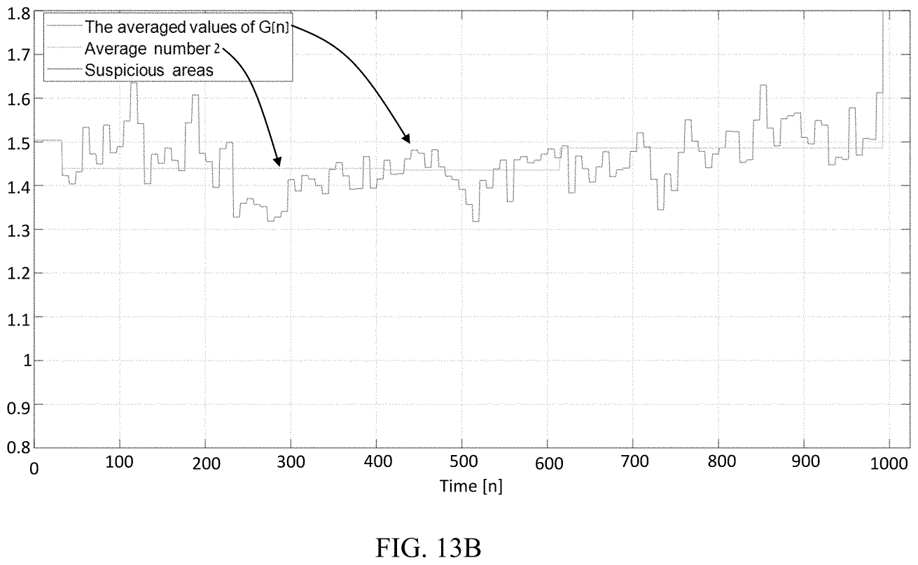

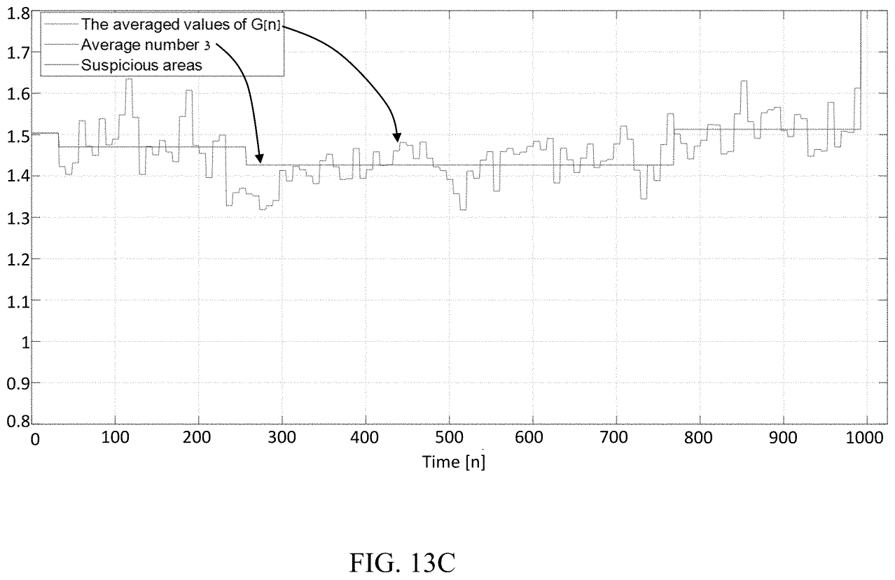

Reference is made now to FIGS. 13A, 13B and 13C, which depict simulated results obtained for a non-random sequence with length of 1024 where the averaged vector G[n] was compared to the three different kind of averages (Average number 1, Average number 2, Average number 3), respectively, in accordance with embodiments of the present disclosure.

This section simulation results are first shown (Table 2) using the Wigner test (the test with the four parameters “power”, “distance”, “density” and “highest”) for identifying if the tested input sequence is a random sequence or not, compared to those obtained with the DFT test from NIST. For this purpose, eight sequences were applied with different number of cycles, with different cycle length and segment position of the cyclic part in the tested sequence. Each structure was tested with a sequence length of 1024, 2048 and 4096 (Section III where the results for the Wigner test are presented and where the tested sequences were defined). According to Table 2, the DFT test from NIST, does not detect in most cases that the non-stationary input sequence is not a random sequence while the Wigner test (the test with the four parameters “power”, “distance”, “density” and “highest”) supplies in most cases the right answer.

TABLE 2
Comparison between the DFT test to Wigner

| | Length of | Wigner | | | | | DFT | |
|---|---|---|---|---|---|---|---|---|
| | sequence | Power | Distance | Density | Highest | Random | P value | Random |
| 1 | 1024 | 0.9-1 | 0.78 | 0.51 | 1208 | no | 1.2168e−04 | no |
| 2 | 1024 | 0.9-1 | 0.72 | 0.56 | 3611 | no | 0.8364 | yes |
| 3 | 1024 | 0.8-0.9 | 0.3 | 0.78 | 18 | no | 0.4559 | yes |
| 4 | 1024 | 0.7-0.8 | 0.25 | 0.88 | 6 | yes | 0.6464 | yes |
| 5 | 1024 | 0.8-0.9 | 0.39 | 0.79 | 19 | no | 0.4913 | yes |
| 6 | 1024 | 0.7-0.8 | 0.3 | 0.9 | 19 | no | 0.4913 | yes |
| 7 | 1024 | 0.9-1 | 0.47 | 0.83 | 36 | no | 0.6881 | yes |
| 8 | 1024 | 0.9-1 | 0.44 | 0.76 | 33 | no | 0.0665 | yes |
| 9 | 2048 | 0.9-1 | 0.75 | 0.6 | 3282 | no | 7.1886e−12 | no |
| 10 | 2048 | 0.9-1 | 0.8 | 0.5 | 9182 | no | 0.7151 | yes |
| 11 | 2048 | 0.7-0.8 | 0.22 | 0.77 | 13 | no | 0.6881 | yes |
| 12 | 2048 | 0.7-0.8 | 0.26 | 0.61 | 7 | no | 0.1215 | yes |
| 13 | 2048 | 0.9-1 | 0.29 | 0.91 | 48 | no | 0.207 | yes |
| 14 | 2048 | 0.7-0.8 | 0.3 | 0.91 | 13 | yes | 0.3304 | yes |
| 15 | 2048 | 0.9-1 | 0.4 | 0.84 | 43 | no | 0.0027 | no |
| 16 | 2048 | 0.9-1 | 0.4 | 0.8 | 51 | no | 0.0167 | yes |
| 17 | 4096 | 0.9-1 | 0.83 | 0.62 | 6346 | no | 1.3041e−21 | no |
| 18 | 4096 | 0.9-1 | 0.7 | 0.51 | 24,527 | no | 0.5281 | yes |
| 19 | 4096 | 0.7-0.8 | 0.25 | 0.72 | 4 | no | 0.1687 | yes |
| 20 | 4096 | 0.7-0.8 | 0.3 | 0.6 | 11 | no | 0.0031 | no |
| 21 | 4096 | 0.9-1 | 0.42 | 0.92 | 84 | no | 0.2758 | yes |
| 22 | 4096 | 0.7-0.8 | 0.35 | 0.93 | 19 | no | 0.0963 | yes |
| 23 | 4096 | 0.9-1 | 0.48 | 0.84 | 96 | no | 0.002 | no |
| 24 | 4096 | 0.9-1 | 0.52 | 0.81 | 124 | no | 0.2175 | yes |

It should be pointed out that the tested input sequences used for generating the results in Table 2 are sequences with a high periodicity within the sequence or have a high length of a repetitive sequence. For this case, the Wigner test (the test with the four parameters “power”, “distance”, “density” and “highest”) is enough for declaring if the tested input sequence is random or not random. But, for sequences with a low periodicity within the sequence the GGD function is needed. In the following a proposed method according to embodiments of the present invention is denoted as the “New test” as described in the previous section and described in FIG. 7 containing the Wigner and the GDD functions.

Table 3 shows a summary of results obtained by the NIST tests 1-8 and by the “New test” algorithm for low-periodic input sequences (2 periods in a signal) and input sequences having a short periodic segment length (100-170 samples of a periodic segment length out of 1024 samples). It can be clearly seen from Table 3, that in most cases the “New test” classifies the incoming sequence as non-random as it should, while the opposite is true for the NIST tests 1-8 [18]. In order to make the comparison, each test was performed 5 times on different sequences to make sure the result was not accidental. In most cases, the new test classifies the incoming sequence as non-random.

TABLE 3
Results Summary

| | Test 1 | Test 2 | Test 3 | Test 4 | Test 5 | Test 6 | |
|---|---|---|---|---|---|---|---|
| Sequence | NIST | NIST | NIST | NIST | NIST | NIST | New Test |
| Periodic sample 1 | 0.95 | 0.518 | 0.348 | 0.959 | 0.1855 | 0.4913 | Not random |
| | 0.26 | 0.556 | 0.144 | 0.925 | 0.7455 | 0.491 | Not random |
| | 0.189 | 0.34 | 0.231 | 0.731 | 0.052 | 0.122 | Not random |
| | 0.189 | 0.804 | 0.537 | 0.849 | — | 0.067 | Not random |
| | 0.169 | 0.367 | 0.799 | 0.841 | — | 0.122 | Not random |
| Periodic sample 2 | 0.104 | 0.197 | 0.047 | 0.445 | 0.053 | 0.067 | Not random |
| | 0.803 | 0.932 | 0.575 | 0.968 | 0.368 | 0.688 | Not random |
| | 0.532 | 0.258 | 0.0541 | 0.7312 | 0.0122 | 0.6881 | Not random |
| | 0.317 | 0.709 | 0.552 | 0.991 | — | 0.207 | Not random |
| | 0.137 | 0.403 | 0.42 | 0.933 | 0.053 | 0.646 | Not random |
| Periodic sample 3 | 0.453 | 0.834 | 0.629 | 0.939 | 0.977 | 0.329 | Not random |
| | 0.317 | 0.598 | 0.247 | 0.866 | — | 0.909 | Not random |
| | 0.608 | 0.559 | 0.163 | 0.563 | 0.033 | 0.207 | Not random |
| | 0.492 | 0.223 | 0.912 | 0.99 | — | 0.0665 | Not random |
| | 0.95 | 0.993 | 0.617 | 0.518 | 0.092 | 0.908 | Not random |
| Periodic sample 4 | 0.617 | 0.836 | 0.497 | 0.907 | 0.746 | 0.491 | Not random |
| | 0.617 | 0.945 | 0.667 | 0.729 | — | 0.456 | Not random |
| | 0.708 | 0.634 | 0.855 | 0.904 | — | 0.207 | Not random |
| | 0.532 | 0.879 | 0.255 | 0.712 | 0.033 | 0.688 | Random |
| | 0.118 | 0.655 | 0.193 | 0.883 | 0.926 | 0.688 | Not random |
| Periodic sample 5 | 0.851 | 0.644 | — | 0.691 | 0.092 | 0.456 | Random |
| | 0.317 | 0.056 | — | 0.995 | — | 0.1215 | Not random |
| | 0.169 | 0.489 | 0.418 | 0.97 | — | 0.688 | Not random |
| | 0.211 | 0.289 | 0.254 | 0.958 | — | 0.491 | Not random |
| | 0.492 | 0.984 | 0.094 | 0.789 | 0.053 | 0.329 | Not random |
| Periodic sample 6 | 1 | 0.997 | 0.803 | 0.461 | 0.033 | 0.646 | Not random |
| | 0.901 | 0.827 | 0.951 | 0.906 | — | 0.909 | Random |
| | 0.754 | 0.308 | 0.19 | 0.967 | — | 0.122 | Not random |
| | 0.382 | 0.197 | 0.144 | 0.777 | — | 0.329 | Not random |
| | 0.249 | 0.912 | 0.436 | 0.991 | 0.092 | 0.688 | Not random |

After categorizing the incoming sequence, the phase of the periodic segment must be performed. For this purpose, the signal of the shape parameter must be characterized so that deviations from the expected signal can be detected. It is noticeable that at the edges the value of this shape parameter is higher because the shape of the distribution takes on a blunt shape, meaning, the values of the matrix at lower edges (for example, and as described elsewhere herein, as obtained in a Gaussian distribution). In contrast, at the center of the signal, a small segment of low values is obtained, which represents the peak height of the distribution, with a lower shape parameter value the shape of the distribution becomes sharper. In other parts the value moves around a uniform value. If this is the case, it is necessary to detect deviations from the expected shape. However, the appearance of a periodic segment during the signal is not uniformly characterized, for example, when the repeating pattern appears in the center of the signal—a segment of lower parameter values is obtained—because the shape of the distribution becomes sharper. However, when the pattern appears at the edges—a segment of high parameter values is obtained. In this case there is a sharp increase (meaning, a low parameter), but the noticeable change is in the high shape parameter values, which means that the gradients around the generated peak can be identified.

Therefore, for the detection three signal performances were preformed, because every other part of the signal when a periodic segment appears, it will be characterized differently. After performance, each part of the signal is measured relative to another (for example, as depicted by FIGS. 13A-13C).

In some embodiments, after activating the detection algorithm, a picture of suspicious areas as periodic areas is received. The algorithm result in most cases marks the periodic segment, but also marks additional areas. These additions do not hurt the result, since after marking a correction will be performed, and therefore the result is a sequence that is more likely to be random.

In some embodiments, the algorithm itself decides on some of the additional areas it detects, so some of the suspicious areas that have been marked are deleted, for example if a single segment is marked and another area of the sequence has a cluster of regions that have been marked—the algorithm will delete the single section.

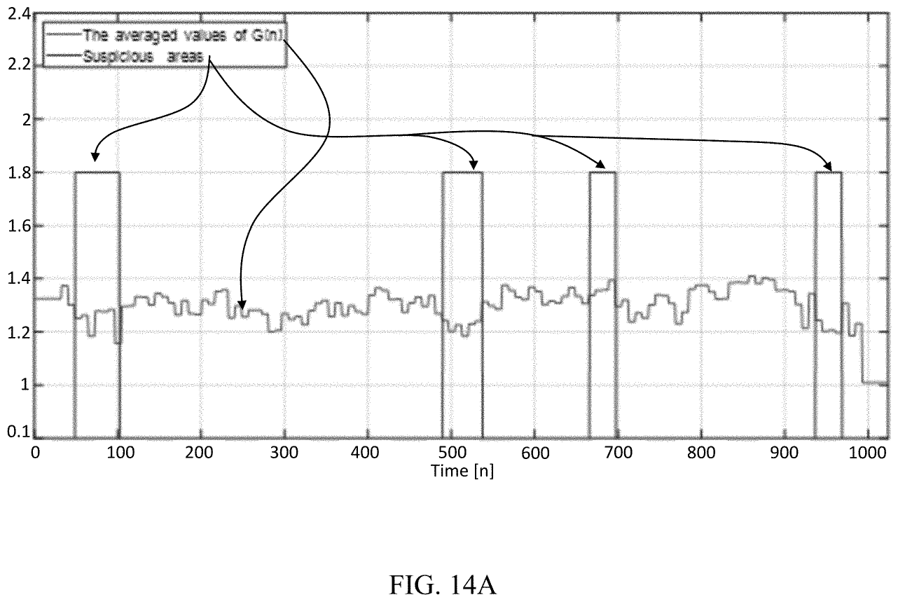

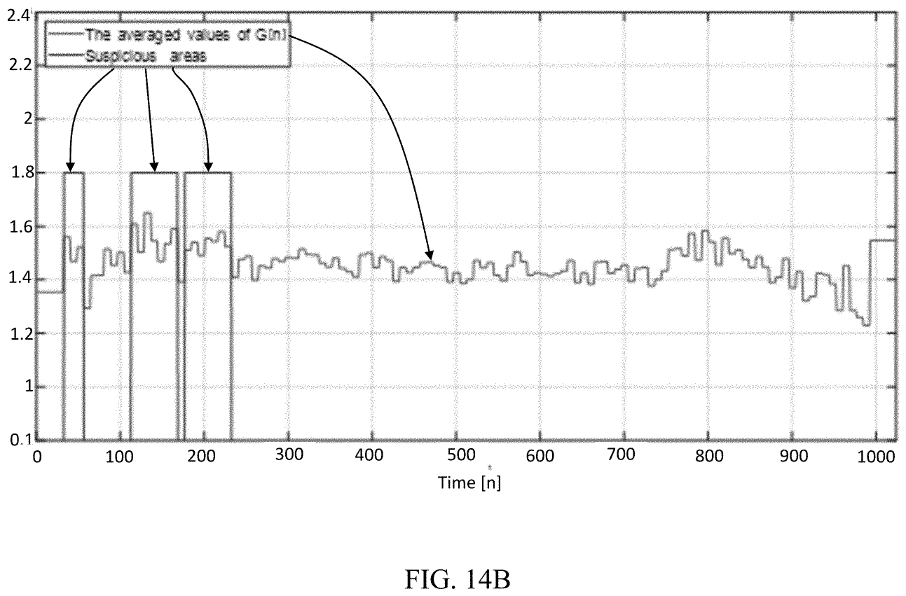

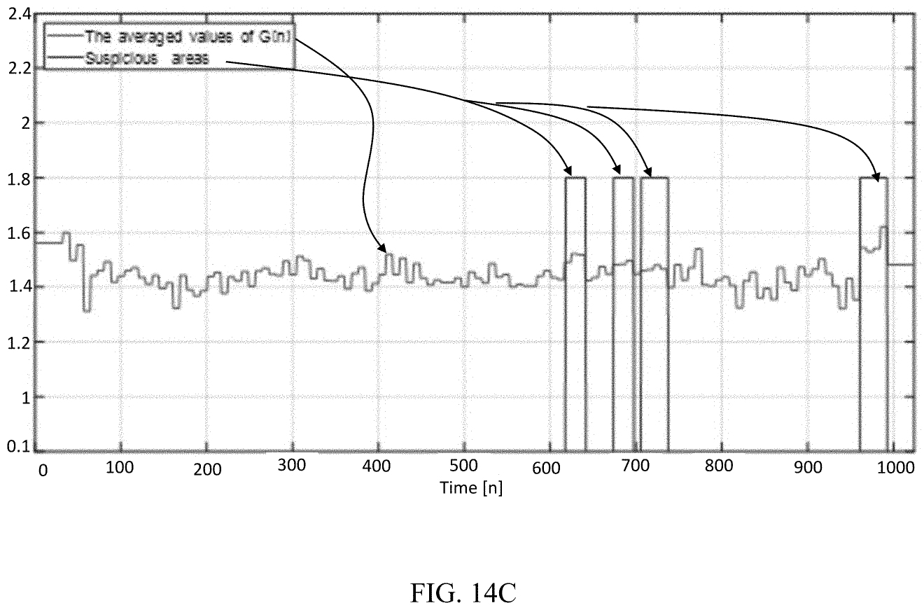

Reference is made to FIGS. 14A-14C, which show exemplary results of the algorithm (rectangular notation) that is pasted on the signal obtained after GGD, in accordance with some embodiments of the present disclosure. FIGS. 14A-14C depict the application of the “New Test” algorithm result on a signal of 1024 samples in the following structures 1-3, respectively (bold letters depict results of zones suspected as non-random):

Structure 1:

y₁(n)=Randomal−150 samples

y₂(n)=Randomal−384 samples

y₃(n)=Randomal−170 samples

m₁(n)=y₃(n),y₂(n),y₃(n),y₁(n),y₃(n)

Structure 2:

y₁(n)=Randomal−150 samples

y₂(n)=Randomal−384 samples

y₃(n)=Randomal−170 samples

m₂(n)=y₁(n),y₃(n),y₂(n),y₃(n),y₄(n)

Structure 3:

y₁(n)=Randomal−100 samples

y₂(n)=Randomal−824 samples

m₃(n)=y₁(n),y₂(n),y₁(n)

As shown in the current description of embodiments of the invention, the proposed new approach for estimating the probability of signal randomness degree based on the Wigner and GGD functions allows to classify the input sequence in the time and frequency domains at the same time. Embodiments of the present invention are suitable also for non-stationary input sequences where the NIST tests fail. In addition, this new proposed algorithm has the ability to indicate on suspicious places of cyclic sections in the tested sequence. Thus, the option to repair or to remove the suspicious places of cyclic sections in the tested input sequence is given with this new approach which was not available until now. Simulation results have confirmed the effectiveness of our new proposed method for estimating the probability of signal randomness degree for non-stationary input sequences. It should be pointed out here that the values for the four parameters (“power”, “distance”, “density” and “highest”) were not optimized. Thus, it is possible to get even better results in identifying if the tested sequence is random or not.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object-oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described herein with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a hardware processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

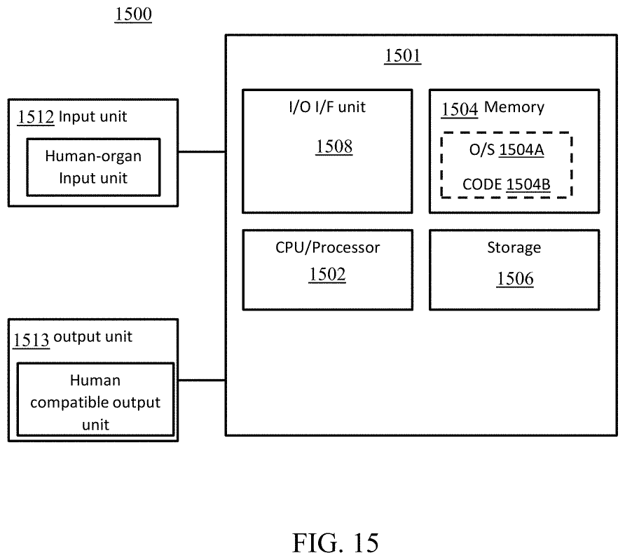

Reference is made now to FIG. 15, which is a block diagram of a computing system 1500 according to embodiments of the present invention. Computing system 1500 may comprise processor 1502, memory unit 1504, storage device 1506 and input/output (I/O) interface (I/F) unit 1508. In some embodiments some or all of components 1502, 1504, 1506 and 1508 may be housed (or embodied) in one computing unit 1501. Computing system 1500 may further comprise input unit 1512 and output unit 1513. Processor 1502 may be, for example, a central processing unit processor (CPU), a chip or any suitable computing or computational device. Processor 1502 (or one or more processors, possibly across multiple units or devices) may be configured to carry out methods described herein, and/or to execute or act as the various modules, units, etc. More than one computing system 1500 may be included in, and one or more computing systems 1500 may act as the components of a system according to embodiments of the invention.

Memory unit 1504 may be or may include, for example, a Random-Access Memory (RAM), a read only memory (ROM), a Dynamic RAM (DRAM), a Synchronous DRAM (SD-RAM), a double data rate (DDR) memory chip, a Flash memory, a volatile memory, a non-volatile memory, a cache memory, a buffer, a short-term memory unit, a long-term memory unit, or other suitable memory units or storage units. Memory 1504 may be or may include a plurality of possibly different memory units. Memory unit 1504 may be a computer or processor non-transitory readable medium, or a computer non-transitory storage medium, e.g., a RAM.

Storage unit 1506 may be or may include, for example, a flash memory as known in the art, a memory that is internal to, or embedded in, a micro controller or chip as known in the art, a hard disk drive, a CD-Recordable (CD-R) drive, a Blu-ray disk (BD), a universal serial bus (USB) storage device or other suitable removable and/or fixed storage unit. Content may be stored in storage unit 1506 and may be loaded from storage unit 1506 into memory unit 1504 where it may be processed by processor 1502. In some embodiments, some of the components shown in FIG. 15 may be omitted. For example, memory unit 1504 may be a non-volatile memory having the storage capacity of storage unit 1506. Accordingly, although shown as a separate component, storage unit 1506 may be embedded or included in memory unit 1504.

Computing system 1500 may further comprise I/O interface (I/F) unit 1508, which is configured to enable communication and connectivity of input unit 1512 and output unit 1513 to computing system 1500. Processor 1502, memory unit 1504, storage unit 1506 and I/O interface unit 1508 may be in operational connection with each other.

Input unit 1512 may be or may include any suitable input devices, components or systems, e.g., a detachable keyboard or keypad, a mouse, a touch screen, a microphone and the like. Output unit 1513 may include one or more (possibly detachable) displays or monitors, speakers and/or any other suitable output devices. Any applicable input/output (I/O) devices may be connected to computing system 1500 as shown by blocks 1512 and 1513. For example, a wired or wireless network interface card (NIC), a universal serial bus (USB) device or external hard drive may be included in input devices 1512 and/or output devices 1513. It will be recognized that any suitable number of input devices 1512 and output device 1513 may be operatively connected to computing system 1500 as shown by blocks 1512 and 1513.

Computing system 1500 may comprise operating system 1054A that may be stored or loaded into memory unit 1504. Operating system 1504A may be or may include any code segment (e.g., one similar to executable code 1504B described herein) designed and/or configured to perform tasks involving coordination, scheduling, arbitration, supervising, controlling or otherwise managing operation of computing system 1500, for example, scheduling execution of software programs or tasks or enabling software programs or other modules or units to communicate. Operating system 1504A may be a commercial operating system. It will be noted that an operating system 1504A may be an optional component, e.g., in some embodiments, a system may include a computing device that does not require or include an operating system 1504A. Computing system may comprise executable code 1504B which may be any executable code, e.g., an application, a program, a process, task or script. Executable code 1504B may be executed by processor 1502, possibly under control of operating system 1504A. Although, for the sake of clarity, a single item of executable code 1504B is shown in FIG. 15, system according to some embodiments of the invention may include a plurality of executable code segments similar to executable code 1504B that may be loaded into memory unit 1504 and cause processor 1502, when executed, to carry out methods described herein.

The flowcharts and block diagrams in the Figures illustrate the architecture, functionality, and operation of possible implementations of systems, methods and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the description and claims of the application, each of the words “comprise” “include” and “have”, and forms thereof, are not necessarily limited to members in a list with which the words may be associated. In addition, where there are inconsistencies between this application and any document incorporated by reference, it is hereby intended that the present application controls.

1. A system comprising:
at least one hardware processor; and
a non-transitory computer-readable storage medium having stored thereon program code, the program code executable by the at least one hardware processor to:
receive a sequence comprising n bits,
apply a transformation to said sequence to obtain a time-frequency signal representation of said sequence,
analyze said signal to measure one or more intensity values of said transformed sequence, and
determine the presence of a periodic segment within said sequence when one of said intensity values deviates from a specified value range.

2. The system of claim 1, wherein said sequence is generated by a random number generator and the step of determining the presence of a periodic segment within said sequence comprises instruction for correcting the sequence to minimize the presence of a periodic segment.

3. The system of claim 1, wherein said transformation comprises applying a Wigner distribution function to said sequence to obtain said time-frequency signal representation.

4. The system of claim 1, wherein said program instructions are further executable to transform said sequence into an analytic signal.

5. The system of claim 4, wherein said transformation comprises applying a Hilbert transform to said sequence.

6. The system of claim 1, wherein said program instructions are further executable to apply a time domain analysis to said time-frequency signal, to obtain a vector representing a distribution of a shape parameter associated with said time-frequency signal.

7. The system of claim 6, wherein said analyzing comprises analyzing said distribution of said shape parameter to detect said deviations.

8. The system of claim 7, wherein said deviations are detected based on at least one of: a maximum intensity peak, a width of an intensity peak, position of an intensity peaks, a number of intensity peaks, and a ratio between two or more intensity peaks,

9. The system of claim 1, wherein said program instructions are further executable to correct at least one of said detected periodic segments.

10. A method comprising:
receiving a sequence comprising n bits;
applying a transformation to said sequence to obtain a time-frequency signal representation of said sequence;
analyzing said signal to measure one or more intensity values of said transformed sequence; and
determining the presence of a periodic segment within said sequence when one of said intensity values deviates from a specified value range.

11. The method of claim 10, wherein said sequence is generated by a random number generator.

12. The method of claim 10, wherein said transformation comprises applying a Wigner distribution function to said sequence to obtain said time-frequency signal representation.

13. The method of claim 10, further comprising a preliminary step of transforming said sequence into an analytic signal.

14. The method of claim 13, wherein said preliminary step comprises applying a Hilbert transform to said sequence.

15. The method of claim 10, further comprising applying a time domain analysis to said time-frequency signal, to obtain a vector representing a distribution of a shape parameter associated with said time-frequency signal.

16. The method of claim 15, wherein said analyzing comprises analyzing said distribution of said shape parameter to detect said deviations.

17. The method of claim 16, wherein said deviations are detected based on at least one of: a maximum intensity peak, a width of an intensity peak, position of an intensity peaks, a number of intensity peaks, and a ratio between two or more intensity peaks,

18. The method of claim 10, further comprising correcting at least one of said detected periodic segments.

19. A computer program product comprising a non-transitory computer-readable storage medium having program code embodied therewith, the program code executable by at least one hardware processor to:
receive a sequence comprising n bits;
apply a transformation to said sequence to obtain a time-frequency signal representation of said sequence;
analyze said signal to measure one or more intensity values of said transformed sequence; and
determine the presence of a periodic segment within said sequence when one of said intensity values deviates from a specified value range.

20. The computer program product of claim 19, wherein said sequence is generated by a random number generator.

21.-27. (canceled)
